(19) United States
(12) Patent Application Publication
(10) Pub. No.: US 2016/0233112 A1
(43) Pub. Date: Aug. 11, 2016

(54) RELEASE FILM FOR CONTROLLING FLOW OF RESIN AND METHOD OF MANUFACTURING SEMICONDUCTOR PACKAGE USING THE SAME

(71) Applicants: Soo-jae PARK, Asan-si (KR); Su-yang LEE, Daegu (KR)

(72) Inventors: Soo-jae PARK, Asan-si (KR); Su-yang LEE, Daegu (KR)

(21) Appl. No.: 14/989,918

(22) Filed: Jan. 7, 2016

(30) Foreign Application Priority Data
Feb. 11, 2015 (KR) 10-2015-0020966

(51) Int. Cl. H01L 21/56; B29C 33/68

(52) U.S. Cl. CPC H01L 21/566; B29C 33/68

(57) ABSTRACT

A release film for controlling a flow of resin includes a backbone layer, a mold release layer on a first surface of the backbone layer, and a resin release layer on a second surface of the backbone layer, a surface of the resin release layer facing away from the backbone layer including regions having contact angles that are different from each other.

### CROSS-REFERENCE TO RELATED APPLICATION

Korean Patent Application No. 10-2015-0020966, filed on Feb. 11, 2015, in the Korean Intellectual Property Office, and entitled: “Release Film for Controlling Flow of Resin and Method of Manufacturing Semiconductor Package Using the Same,” is incorporated by reference herein in its entirety.

### BACKGROUND

1. Field

Embodiments relate to a release film for controlling a flow of resin and a method of manufacturing a semiconductor package using the release film. More particularly, embodiments relate to a release film for controlling a flow of resin for forming an encapsulant that is used in a semiconductor package and a method of manufacturing a semiconductor package using the release film.

2. Description of the Related Art

With the rapid development of electronic industries and increased user demand, electronic devices are being further miniaturized and multi-functionalized. Consequently, semiconductor packages that are used in electronic devices are also required to be miniaturized. Thus, it is necessary to minimize the volume of an encapsulant for encapsulating the semiconductor packages.

### SUMMARY

According to an aspect of embodiments, there is provided a release film for controlling a flow of resin that includes a backbone layer, a mold release layer on a first surface of the backbone layer, and a resin release layer on a second surface of the backbone layer, a surface of the resin release layer facing away from the backbone layer including regions having contact angles that are different from each other.

The resin release layer may include a first resin release layer and a second release layer, sequentially attached to the backbone layer, wherein the first resin release layer and the second release layer have different contact angles in the surface opposite to the backbone layer.

A contact angle in the first resin release layer may be larger than that in the second resin release layer.

A contact angle in the second resin release layer may be larger than that in the first resin release layer.

The surface of the resin release layer which faces away from the backbone layer may include a first region and a second region, and a contact angle in the first region may be smaller than that in the second region.

The second region may have a plurality of linear stripe shapes that extend in a first direction and are parallel to each other.

The first direction may be a direction perpendicular to an injection direction of the resin.

The first direction may be an injection direction of the resin.

The second region may have a plurality of chevron stripe shapes that are repeatedly arranged.

The second region may have a plurality of bar shapes that are arranged in a matrix form.

An area of the second region may be smaller than that of the first region.

An average roughness of the second region may be greater than that of the first region.

The surface of the resin release layer which faces away from the backbone layer may include regions having different average roughness values.

A contact angle in at least a part of the surface of the resin release layer which faces away from the backbone layer may have a gradient.

The mold release layer may be an adhesive layer.

According to another aspect of embodiments, there is provided a release film for controlling a flow of resin including an adhesive surface, and a resin flow control surface that is opposite to the adhesive surface, the resin flow control surface including first and second regions having contact angles that are different from each other.

The release film may further include a backbone layer, and a first resin release layer and a second release layer, sequentially attached on the backbone layer to form the resin flow control surface, wherein the first resin release layer and the second release layer have different contact angles in a surface opposite to the backbone layer, wherein the second resin release layer is disposed in the second region.

The second region may have a plurality of linear stripe shapes that are attached on the first resin release layer so as to be separate from each other and arranged parallel to each other.

In the surface opposite to the backbone layer, a contact angle of the second resin release layer may be larger than that of the first resin release layer, and an uneven portion may be formed in a part of the first resin release layer.

The part of the first resin release layer in which the uneven portion is formed may have a contact angle that is larger than that of a remaining part of the first resin release layer.

The part of the first resin release layer in which the uneven portion is formed may have a contact angle that is smaller than that of the second resin release layer.

The first resin release layer may include at least two regions having different average roughness values.

An uneven portion may be formed in the second region of the resin flow control surface.

According to still another aspect of embodiments, there is provided a method of manufacturing a semiconductor package, the method including preparing a mold having a cavity surface that defines a cavity, preparing a release film including a backbone layer, a mold release layer on a first surface of the backbone layer, and a resin release layer on a second surface of the backbone layer, attaching the release film to the cavity surface of the mold so that the mold release layer faces the cavity surface, accommodating a semiconductor chip in the cavity, injecting resin into the cavity in a first direction, and separating a semiconductor chip encapsulated with the resin from the release film, wherein a surface of the resin release layer facing away from the backbone layer including regions having contact angles that are different from each other.

The resin release layer may include a first region and a second region, wherein a contact angle of a surface of the second region is larger than that of a surface of the first region.

The second region may have a plurality of linear stripe shapes that extend in a second direction perpendicular to the first direction and are parallel to each other.

In the accommodating of the semiconductor chip in the cavity, the semiconductor chip may be accommodated in the cavity so that the semiconductor chip is disposed to intersect at least one of the plurality of linear stripe shapes of the second region.

The second region may have a plurality of linear stripe shapes that extend in a first direction and are parallel to each other.

In the accommodating of the semiconductor chip in the cavity, the semiconductor chip may be accommodated in the cavity so that the semiconductor chip is disposed along the first region.

In the accommodating of the semiconductor chip in the cavity, the semiconductor chip may be accommodated in the cavity so that a part of the semiconductor chip is disposed to overlap the second region.

According to yet another aspect of embodiments, there is provided a release film for controlling a flow of resin, the release film including a backbone layer, a mold release layer on a first surface of the backbone layer, and a resin release layer on a second surface of the backbone layer, the second surface of the backbone layer being opposite the first surface, and a surface of the resin release layer facing away from the backbone layer including first surface portions having a first contact angle and second surface portions having a second contact angle larger than the first contact angle.

The first surface portions may include a different material than the second surface portions.

The first surface portions may exhibit a lower roughness value than the second surface portions.

The first surface portions may be at a different distance from the second surface of the backbone layer relative to the second surface portions.

The first surface portions may alternate with the second surface portions.

### BRIEF DESCRIPTION OF THE DRAWINGS

Features will become apparent to those of ordinary skill in the art by describing in detail exemplary embodiments with reference to the attached drawings, in which:

FIG. 1 illustrates a cross-sectional view of a release film for controlling a flow of resin, according to an exemplary embodiment;

FIG. 2 illustrates a cross-sectional view of a release film for controlling a flow of resin, according to another exemplary embodiment;

FIG. 3 illustrates a cross-sectional view of a release film for controlling a flow of resin, according to another exemplary embodiment;

FIG. 4 illustrates a cross-sectional view of a release film for controlling a flow of resin, according to another exemplary embodiment;

FIG. 5 illustrates a cross-sectional view of a release film for controlling a flow of resin, according to another exemplary embodiment;

FIG. 6 illustrates a cross-sectional view of a release film for controlling a flow of resin, according to another exemplary embodiment;

FIG. 7 illustrates a cross-sectional view of a release film for controlling a flow of resin, according to another exemplary embodiment;

FIG. 8 illustrates a cross-sectional view of a release film for controlling a flow of resin, according to another exemplary embodiment;

FIG. 9 illustrates a cross-sectional view of a release film for controlling a flow of resin, according to another exemplary embodiment;

FIG. 10 illustrates a diagram for comparing contact angles in regions of a resin release layer included in a release film for controlling a flow of resin, according to an exemplary embodiment;

FIG. 11 illustrates a diagram of a change in a contact angle according to the position of a resin release layer included in a release film for controlling a flow of resin, according to an exemplary embodiment;

FIG. 12 illustrates a cross-sectional view of a method of manufacturing a semiconductor package, according to an exemplary embodiment;

FIG. 13 illustrates a cross-sectional view of a method of manufacturing a semiconductor package, according to another exemplary embodiment;

FIG. 14 illustrates a plan view of a resin release layer included in a release film for controlling a flow of resin, according to an exemplary embodiment;

FIG. 15 illustrates a plan view of a resin release layer included in a release film for controlling a flow of resin, according to another exemplary embodiment;

FIG. 16 illustrates a plan view of a resin release layer included in a release film for controlling a flow of resin, according to another exemplary embodiment;

FIG. 17 illustrates a plan view of a resin release layer included in a release film for controlling a flow of resin, according to another exemplary embodiment;

FIG. 18 illustrates a cross-sectional view of a method of manufacturing a semiconductor package, according to another exemplary embodiment;

FIG. 19 illustrates a plan view of a resin release layer included in a release film for controlling a flow of resin, according to another exemplary embodiment;

FIG. 20 illustrates a plan view of a resin release layer included in a release film for controlling a flow of resin, according to another exemplary embodiment;

FIG. 21 illustrates a flowchart of a method of manufacturing a semiconductor package, according to an exemplary embodiment;

FIG. 22 illustrates a plan view of a memory module including a semiconductor package according to any one of the exemplary embodiments;

FIG. 23 illustrates a perspective view of an electronic device including a semiconductor package according to any one of the exemplary embodiments; and

FIGS. 24 to 26 illustrate diagrams of multimedia devices using a semiconductor package according to any one of the exemplary embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers, regions, and ratios may be exaggerated for clarity of illustration. It will be understood that when an element, such as a layer, a region, or a substrate, is referred to as being “on,” “connected to” or “coupled to” another element, it may be directly on, connected or coupled to the other element or intervening elements may be present. Other expressions, such as, “between” and “directly between”, describing the relationship between the constituent elements, may be construed in the same manner. Like reference numerals refer to like elements throughout.

The terms such as “first” and “second” are used herein merely to describe a variety of constituent elements, but the constituent elements are not limited by the terms. The terms are used only for the purpose of distinguishing one constituent element from another constituent element. For example, without departing from the right scope of the embodiments, a first constituent element may be referred to as a second constituent element, and vice versa.

The expression of singularity in the present specification includes the expression of plurality unless clearly specified otherwise in context. Also, the terms such as “include” or “comprise” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

Unless defined otherwise, all terms used herein including technical or scientific terms have the same meanings as those generally understood by those skilled in the art. As used herein, the term “and/or” includes any and all combinations of one or more of the associated listed items. Expressions such as “at least one of,” when preceding a list of elements, modify the entire list of elements and do not modify the individual elements of the list.

Hereinafter, exemplary embodiments are described in detail in connection with attached drawings.

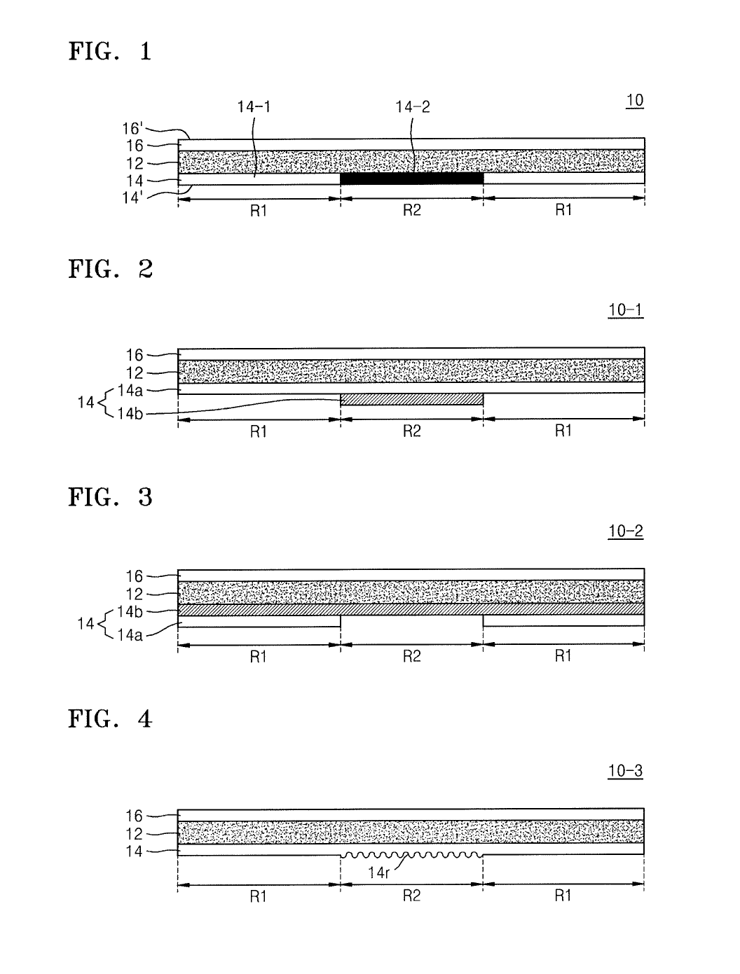

FIG. 1 is a cross-sectional view of a release film 10 for controlling a flow of resin, according to an exemplary embodiment.

Referring to FIG. 1, the release film 10 may include a backbone layer 12, a resin release layer 14, and a mold release layer 16. The resin release layer 14 and the mold release layer 16 are attached to both sides of the backbone layer 12, respectively, e.g., the resin release layer 14 and the mold release layer 16 are attached to opposite surfaces of the backbone layer 12. For example, the backbone layer 12 may have a thickness of several μm to several tens of μm. The backbone layer 12 may be formed of, e.g., a thermoplastic polymer.

The resin release layer 14 and the mold release layer 16 may each have a thickness of several hundreds of nm to several μm. The resin release layer 14 may be formed of, e.g., a copolymer of acrylic and silicone. The mold release layer 16 may also be formed of, e.g., a copolymer of acrylic and silicone.

The resin release layer 14 and/or the mold release layer 16 may be an adhesive layer. A first surface 14′ of the resin release layer 14, which faces away from the backbone layer 12, may be referred to as a resin flow control surface 14′, and a first surface 16′ of the mold release layer 16, which faces away from the backbone layer 12, may be referred to as an adhesive surface 16′.

The resin release layer 14 may include a first region R1 and a second region R2. A portion of the first surface 14′ of a first part 14-1 (i.e., a part of the first region R1), which faces away from the backbone layer 12, and a portion of the first surface 14′ of a second part 14-2 (i.e., a part of the second region R2), which faces away from the backbone layer 12, may have different contact angles. Surfaces of the first and second parts 14-1 and 14-2 correspond to the bottom surface of the release film 10 of FIG. 1.

The contact angle is an angle that is measured when liquid meets, e.g., contacts, a solid surface. In general, when a water contact angle at a solid surface is less than 90 degrees, the solid surface may be regarded as hydrophobic. On the other hand, when the water contact angle at the solid surface is equal to or greater than 90 degrees, the solid surface may be regarded as hydrophilic.

However, a value of the contact angle may vary according to a type of resin of which a flow is to be controlled. Thus, in the current specification, when a contact angle is relatively large at the first surface 14′ of the resin release layer 14, which faces away from the backbone layer 12, the first surface 14′ of the resin release layer 14 may be regarded as hydrophilic. On the other hand, when the contact angle is relatively small at the first surface 14′ of the resin release layer 14, which faces away from the backbone layer 12, the first surface 14a of the resin release layer 14 may be regarded as hydrophobic. In addition, the hydrophobic surface of the resin release layer 14, which faces away from the backbone layer 12, may be regarded as stronger when the contact angle is relatively large at the surface of the resin release layer 14, compared to when the contact angle is relatively small at the surface of the resin release layer 14.

For example, in the first surface 14′ of the resin release layer 14, which faces away from the backbone layer 12, a contact angle in the second region R2 may be larger than that in the first region R1. For example, in the first surface 14′ of the resin release layer 14, which faces away from the backbone layer 12, a water contact angle in the second region R2 may be equal to or greater than 90 degrees and a water contact angle in the first region R1 may be equal to or less than 50 degrees. In this case, in the first surface 14′ of the resin release layer 14, which faces away from the backbone layer 12, a flow of resin along the first region R1 and the second region R2 may be faster in the first region R1 than in the second region R2.

In the first surface 14′ of the resin release layer 14, which faces away from the backbone layer 12, a flow of the resin from the first region R1 toward the second region R2 may not proceed to the second region R2 until the resin reaches all parts of a boundary between the first region R1 and the second region R2. In other words, the second region R2 of the resin release layer 14, in which a contact angle is relatively large, may function as a barrier to the flow of the resin. After the resin reaches all parts of the boundary between the first region R1 and the second region R2, the flow of the resin may proceed to the second region R2.

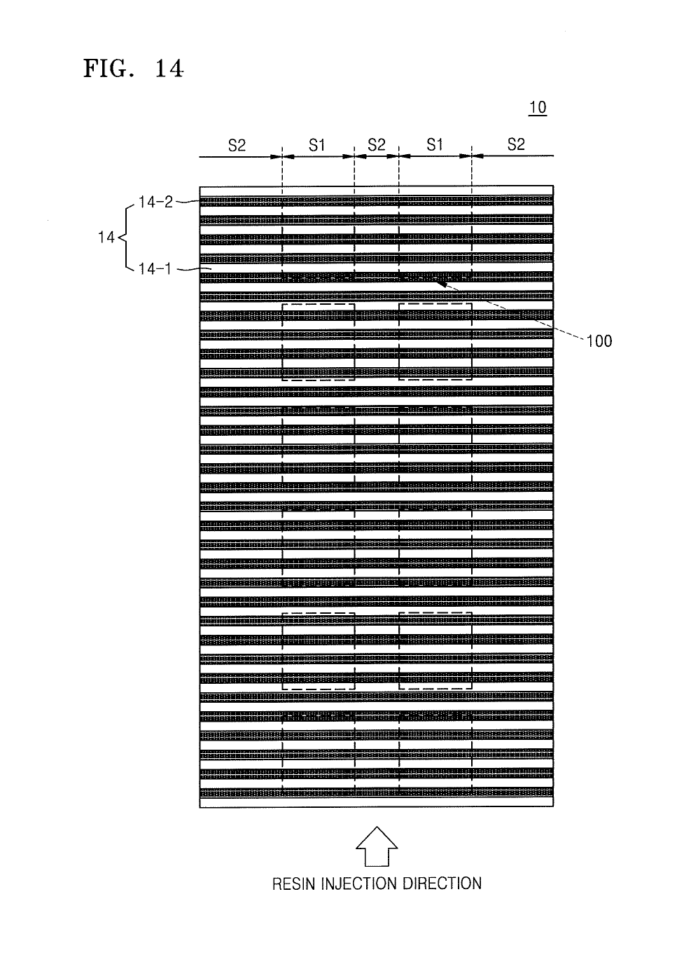

When an area, through which the resin passes, on a surface perpendicular to a direction to which the resin flows is relatively small, the flow of the resin may be relatively slow. When the area is relatively large, the flow of the resin may be relatively fast. Accordingly, when the first region R1, in which a contact angle is relatively small, and the second region R2, in which a contact angle is relatively large, are disposed by taking into account a difference in a flow speed of the resin on the first surface 14′ of the resin release layer 14, which faces away from the backbone layer 12, the flow of the resin may be controlled. This will be described in more detail below with reference to FIG. 14.

Due to a state or material of a surface, which faces away from the backbone layer 12, of each of the first and second parts 14-1 and 14-2 of the resin release layer 14, a surface, which faces away from the backbone layer 12, of the first part 14-1 of the resin release layer 14 and a surface, which faces away from the backbone layer 12, of the second part 14-2 of the resin release layer 14 may have different contact angles. For example, the first and second parts 14-1 and 14-2 may include different materials from each other or different surface treatments from each other that impart different contact angles thereto.

For example, a dry etching process by plasma, a wet etching process by chemicals, a nanosphere lithography process, a laser process, a photolithography process, an electron beam lithography process, a nanowire formation process, a nanotube formation process, a nanoparticle formation process, a fluoride treatment, or an electrochemical deposition process may be performed on a portion of the first surface 14′ of the second part 14-2 of the resin release layer 14 to increase a contact angle in the surface so that the surface is relatively hydrophobic. A contact angle of a portion of the first surface 14′ of the first part 14-1 of the resin release layer 14 may be substantially the same as that of the first surface 16′, which faces away from the backbone layer 12, of the mold release layer 16.

FIG. 2 is a cross-sectional view of a release film 10-1 for controlling a flow of resin, according to another exemplary embodiment.

Referring to FIG. 2 the release film 10-1 may include the backbone layer 12, a resin release layer 14 including first and second resin release layers 14a and 14b sequentially attached to a first surface of the backbone layer 12, and the mold release layer 16 attached to a second surface of the backbone layer 12. The first resin release layer 14a may have a thickness of several hundreds of nm to several μm. The second resin release layer 14b may have a thickness that is similar to that of the first resin release layer 14a, but is not limited thereto. For example, the second resin release layer 14b may have a thickness of several tens of Å to several hundreds of Å.

The first resin release layer 14a and the second resin release layer 14b may have different contact angles at surfaces thereof that are opposite to the backbone layer 12. The first resin release layer 14a may be attached, e.g., directly, to the first surface of the backbone layer 12 so as to cover both the first region R1 and the second region R2 on the backbone layer 12. The second resin release layer 14b may be attached to the first resin release layer 14a so as to cover the second region R2 on the first resin layer 14a but not cover the first region R1 on the first resin release layer 14a. In other words, as illustrated in FIG. 2, the second resin release layer 14b may only partially cover the first resin release layer 14a, so portions of the first resin release layer 14a may exposed in the first region R1.

In detail, the first resin release layer 14a may be exposed in the first region R1 of the first surface 14′ of the resin release layer 14, which faces away from the backbone layer 12, and the second resin release layer 14b may be exposed in the second region R2 of the first surface 14′ of the resin release layer 14. As such, as illustrated in FIG. 2, a total thickness of the resin release layer 14 is larger in the second region R2 than in the first region R1.

For example, the surface of the second resin release layer 14b, which faces away from the backbone layer 12, may have a contact angle that is larger than that in the surface of the first resin release layer 14a, which faces away from the backbone layer 12. In this case, in the first surface 14′ of the resin release layer 14, which faces away from the backbone layer 12, a contact angle in the second region R2 may be larger than that in the first region R1.

The material of the first resin release layer 14a may have substantially the same contact angle as the material of the mold release layer 16. The first resin release layer 14a may be formed of the same material as the mold release layer 16.

FIG. 3 is a cross-sectional view of a release film 10-2 for controlling a flow of resin, according to another exemplary embodiment.

Referring to FIG. 3, the release film 10-2 may include the backbone layer 12, the resin release layer 14 including second and first resin release layers 14b and 14a sequentially attached to the first surface of the backbone layer 12, and the mold release layer 16 attached to the second surface of the backbone layer 12. The second resin release layer 14b may have a thickness of several hundreds of nm to several μm. The first resin release layer 14a may have a thickness that is similar to that of the second resin release layer 14b, but is not limited thereto. For example, the first resin release layer 14a may have a thickness of several tens of Å to several hundreds of Å.

The first resin release layer 14a and the second resin release layer 14b may have different contact angles at surfaces thereof that are opposite to the backbone layer 12. The second resin release layer 14b may be attached to the backbone layer 12 so as to cover both the first region R1 and the second region R2 on the backbone layer 12. The first resin release layer 14a may be attached to the second resin release layer 14b so as to cover the first region R1 on the second resin release layer 14b but not cover the second region R2 on the second resin release layer 14b. As such, as illustrated in FIG. 3, a total thickness of the resin release layer 14 is larger in the first region R1 than in the second region R2.

The first resin release layer 14a may be exposed in the first region R1 of a surface of the resin release layer 14, which faces away from the backbone layer 12, and the second resin release layer 14b may be exposed in the second region R2 of the surface of the resin release layer 14. For example, the surface of the second resin release layer 14b, which faces away from the backbone layer 12, may have a contact angle that is larger than that in the surface of the first resin release layer 14a, which faces away from the backbone layer 12. In this case, in the surface of the resin release layer 14, which faces away from the backbone layer 12, a contact angle in the second region R2 may be larger than that in the first region R1, e.g., due to the difference in layer thickness in the different regions of the resin release layer 14 and/or material thereof.

FIG. 4 is a cross-sectional view of a release film 10-3 for controlling a flow of resin, according to another exemplary embodiment.

Referring to FIG. 4, the release film 10-3 may include the backbone layer 12, a resin release layer 14 attached to the first surface of the backbone layer 12, and the mold release layer 16 attached to the second surface of the backbone layer 12.

The average roughness of the first region R1 of a surface of the resin release layer 14, which faces away from the backbone layer 12, may be different from that of the second region R2 of the surface of the resin release layer 14. For example, the average roughness of the second region R2 of the surface of the resin release layer 14, which faces away from the backbone layer 12, may be greater than that of the first region R1 of the surface of the resin release layer 14.

In detail, an uneven portion 14r may be formed in the second region R2 of the surface of the resin release layer 14, which faces away from the backbone layer 12. In this case, in the surface of the resin release layer 14, which faces away from the backbone layer 12, a contact angle in the second region R2 may be larger than that in the first region R1. For example, in the surface of the resin release layer 14, which faces away from the backbone layer 12, the contact angle in the second region R2 may be larger than that in the first region R1 by about 20 degrees or more.

The resin release layer 14 may be formed of the same material as the mold release layer 16. A contact angle in the first region R1 of the surface of the resin release layer 14, which faces away from the backbone layer 12, may be substantially the same as that in the surface of the mold release layer 16, which faces away from the backbone layer 12.

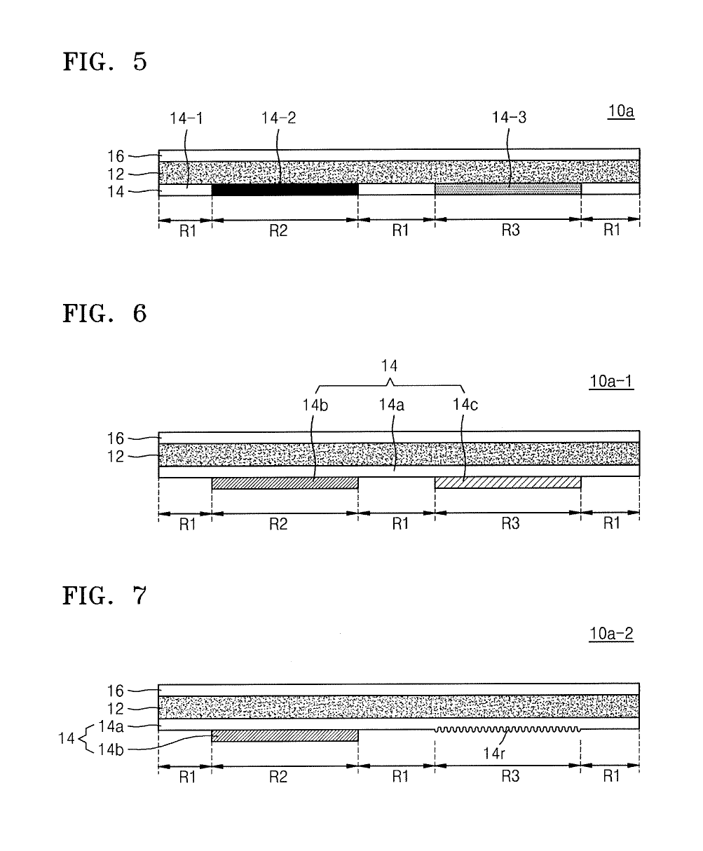

FIG. 5 is a cross-sectional view of a release film 10a for controlling a flow of resin, according to another exemplary embodiment.

Referring to FIG. 5, the release film 10a may include the backbone layer 12, a resin release layer 14 attached to the first surface of the backbone layer 12, and the mold release layer 16 attached to the second surface of the backbone layer 12.

The resin release layer 14 may include a first region R1, a second region R2, and a third region R3. A surface of a first part 14-1 (i.e., a part of the first region R1), which faces away from the backbone layer 12, a surface of a second part 14-2 (i.e., a part of the second region R2), which faces away from the backbone layer 12, and a surface of a third part 14-3 (i.e., a part of the third region R3), which faces away from the backbone layer 12, may have different contact angles. Surfaces of the first, second, and third parts 14-1, 14-2, and 14-3 correspond to the bottom surface of the release film 10a of FIG. 5.

For example, in a surface of the resin release layer 14, which faces away from the backbone layer 12, a contact angle in the second region R2 may be larger than that in the first region R1, and a contact angle in the third region R3 may be smaller than that in the second region R2 and be larger than that in the first region R1. For example, in the surface of the resin release layer 14, which faces away from the backbone layer 12, a water contact angle in the second region R2 may be equal to or greater than about 90 degrees, a water contact angle in the third region R3 may be about 60 degrees to about 80 degrees, and a water contact angle in the first region R1 may be equal to or less than about 50 degrees. For example, the different contact angles of the first through third regions R1 through R3 may be achieved in a same way described previously with reference to FIG. 1.

In FIG. 5, although the second region R2 is separate from the third region R3, embodiments are not limited thereto. For example, the second region R2 and the third region R3 may abut each other.

FIG. 6 is a cross-sectional view of a release film 10a-1 for controlling a flow of resin, according to another exemplary embodiment.

Referring to FIG. 6, the release film 10a-1 may include the backbone layer 12, a resin release layer 14 attached to the first surface of the backbone layer 12, and the mold release layer 16 attached to the second surface of the backbone layer 12. The resin release layer 14 includes a first resin release layer 14a attached on the first surface of the backbone layer 12 and second and third resin release layers 14b and 14c attached on the first resin release layer 14a. The first resin release layer 14a may have a thickness of several hundreds of nm to several p.m. Each of the second and third resin release layers 14b and 14c may have a thickness that is similar to that of the first resin release layer 14a, but is not limited thereto. For example, each of the second and third resin release layers 14b and 14c may have a thickness of several tens of Å to several hundreds of Å.

The first resin release layer 14a, the second resin release layer 14b, and the third resin release layer 14c may have different contact angles at surfaces thereof that are opposite to the backbone layer 12.

The first resin release layer 14a may be attached to the backbone layer 12 so as to cover the first region R1, the second region R2, and the third region R3 on the backbone layer 12. The second resin release layer 14b and the third resin release layer 14c may be attached to the first resin release layer 14a so as to cover the second region R2 and the third region R3 on the first resin layer 14a, respectively, but not cover the first region R1 on the first resin layer 14a.

The first resin release layer 14a, the second resin release layer 14b, and the third resin release layer 14c may be exposed respectively in the first region R1, the second region R2, and the third region R3 of a surface of the resin release layer 14, which faces away from the backbone layer 12.

For example, the surface of the second resin release layer 14b, which faces away from the backbone layer 12, may have a contact angle that is larger than in the surface of the first resin release layer 14a, which faces away from the backbone layer 12. For example, the surface of the third resin release layer 14c, which faces away from the backbone layer 12, may have a contact angle that is smaller than in the surface of the second resin release layer 14b, which faces away from the backbone layer 12, and that is larger than in the surface of the first resin release layer 14a, which faces away from the backbone layer 12. In this case, in the surface of the resin release layer 14, which faces away from the backbone layer 12, a contact angle in the second region R2 may be larger than in the third region R3, and a contact angle in the third region R3 may be larger than in the first region R1.

FIG. 7 is a cross-sectional view of a release film 10a-2 for controlling a flow of resin, according to another exemplary embodiment.

Referring to FIG. 7, the release film 10a-2 may include the backbone layer 12, a resin release layer 14 attached to the first surface of the backbone layer 12, and the mold release layer 16 attached to the second surface of the backbone layer 12. The resin release layer 14 includes a first resin release layer 14a attached on the first surface of the backbone layer 12 and a second resin release layer 14b attached on the first resin release layer 14a. The second resin release layer 14b may be attached on the second region R2 of the first resin release layer 14a. The first resin release layer 14a may have a thickness of several hundreds of nm to several μm. The second resin release layer 14b may have a thickness that is similar to that of the first resin release layer 14a, but is not limited thereto. For example, the second resin release layer 14b may have a thickness of several tens of Å to several hundreds of Å.

The average roughness of a part of a surface of the first resin release layer 14a, which faces away from the backbone layer 12, may be different from that of a remaining part of the surface of the first resin release layer 14a. For example, the average roughness of a third region R3 of the surface of the first resin release layer 14a, which faces away from the backbone layer 12, may be greater than that of a first region R1 of the surface of the first resin release layer 14a. An uneven portion 14r may be formed in the third region R3 of the surface of the first resin release layer 14a, which faces away from the backbone layer 12. In this case, in the surface of the first resin release layer 14a, which faces away from the backbone layer 12, a contact angle in the third region R3 may be larger than that in the first region R1. For example, in the surface of the first resin release layer 14a, which faces away from the backbone layer 12, the contact angle in the third region R3 may be larger than that in the first region R1 by about 20 degrees or more.

A contact angle in a surface of the second resin release layer 14b, which faces away from the backbone layer 12, may be larger than that in the third region R3 of the surface of the first resin release layer 14a, which faces away from the backbone layer 12. In this case, in a surface of the resin release layer 14, which faces away from the backbone layer 12, a contact angle in the second region R2 may be larger than that in the third region R3, and a contact angle in the third region R3 may be larger than that in the first region R1.

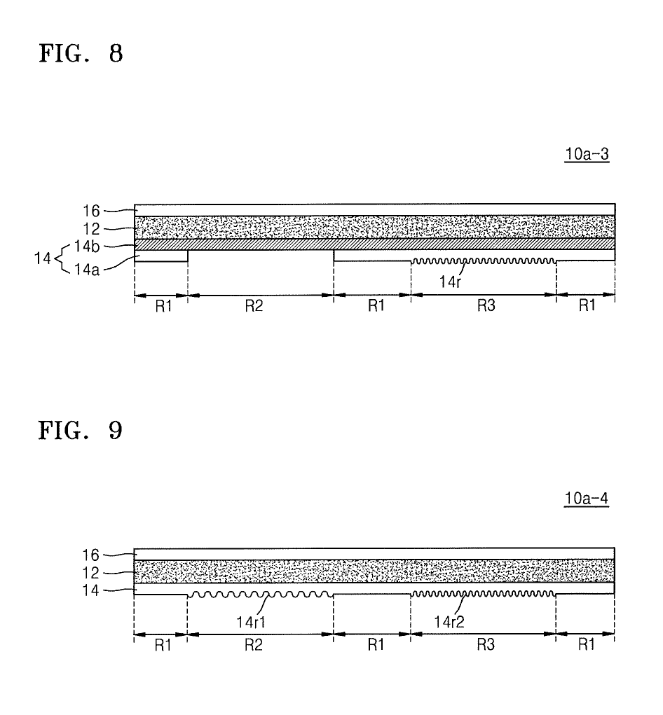

FIG. 8 is a cross-sectional view of a release film 10a-3 for controlling a flow of resin, according to another exemplary embodiment.

Referring to FIG. 8, the release film 10a-3 may include the backbone layer 12, a resin release layer 14 attached to the first surface of the backbone layer 12, and the mold release layer 16 attached to the second surface of the backbone layer 12. The resin release layer 14 includes a second resin release layer 14b attached on the first surface of the backbone layer 12 and a first resin release layer 14a attached on the second resin release layer 14b. The first resin release layer 14a may be attached on first and third regions R1 and R3 of the second resin release layer 14b. The first resin release layer 14a may be attached on the second resin release layer 14b and expose a second region R2 of the second resin release layer 14b. The second resin release layer 14b may have a thickness of several hundreds of nm to several μm. The first resin release layer 14a may have a thickness that is similar to that of the second resin release layer 14b, but is not limited thereto. For example, the first resin release layer 14a may have a thickness of several tens of Å to several hundreds of Å.

The average roughness of a part of a surface of the first resin release layer 14a, which faces away from the backbone layer 12, may be different from that of a remaining part of the surface of the first resin release layer 14a. For example, the average roughness of a third region R3 of the surface of the first resin release layer 14a, which faces away from the backbone layer 12 may be greater than that of a first region R1 of the surface of the first resin release layer 14a. An uneven portion 14r may be formed in the third region R3 of the surface of the first resin release layer 14a, which faces away from the backbone layer 12. In this case, in the surface of the first resin release layer 14a, which faces away from the backbone layer 12, a contact angle in the third region R3 may be larger than that in the first region R1. For example, in the surface of the first resin release layer 14a, which faces away from the backbone layer 12, the contact angle in the third region R3 may be larger than that in the first region R1 by about 20 degrees or more.

A contact angle in a surface of the second resin release layer 14b, which faces away from the backbone layer 12, may be larger than that in the third region R3 of the surface of the first resin release layer 14a, which faces away from the backbone layer 12. In this case, in a surface of the resin release layer 14, which faces away from the backbone layer 12, a contact angle in the second region R2 may be larger than that in the third region R3, and a contact angle in the third region R3 may be larger than that in the first region R1.

FIG. 9 is a cross-sectional view of a release film 10a-4 for controlling a flow of resin, according to another exemplary embodiment.

Referring to FIG. 9, the release film 10a-4 may include the backbone layer 12, a resin release layer 14 attached to the first surface of the backbone layer 12, and the mold release layer 16 attached to the second surface of the backbone layer 12. A surface of the resin release layer 14, which faces away from the backbone layer 12, may include regions having different average roughness.

For example, the average roughness of a second region R2 and a third region R3 of the surface of the resin release layer 14, which faces away from the backbone layer 12, may be greater than that of a first region R1 of the surface of the resin release layer 14. Uneven portions, i.e., a first uneven portion 14r1 and a second uneven portion 14r2, may be respectively formed in the second region R2 and the third region R3 of the surface of the resin release layer 14, which faces away from the backbone layer 12. In this case, in the surface of the resin release layer 14, which faces away from the backbone layer 12, a contact angle in the second and third regions R2 and R3 may be larger than that in the first region R1. For example, in the surface of the resin release layer 14, which faces away from the backbone layer 12, the contact angle in the second and third regions R2 and R3 may be larger than that in the first region R1 by about 20 degrees or more.

The second region R2 and the third region R3 of the surface of the resin release layer 14, which faces away from the backbone layer 12, may have different average roughness values. As described above, the first uneven portion 14r1 and the second uneven portion 14r2 may be respectively formed in the second region R2 and the third region R3 of the surface of the resin release layer 14, which faces away from the backbone layer 12. For example, the average roughness of the second region R2, i.e., the average roughness caused by the first uneven portion 14r1, may be greater than the average roughness of the third region R3, i.e., the average roughness caused by the second uneven portion 14r2. In this case, in the surface of the resin release layer 14, which faces away from the backbone layer 12, a contact angle in the second region R2 may be larger than that in the first region R1. Also, in this case, in the surface of the resin release layer 14, which faces away from the backbone layer 12, the contact angle in the second region R2 may be larger than that in the third region R3, and the contact angle in the third region R3 may be larger than that in the first region R1.

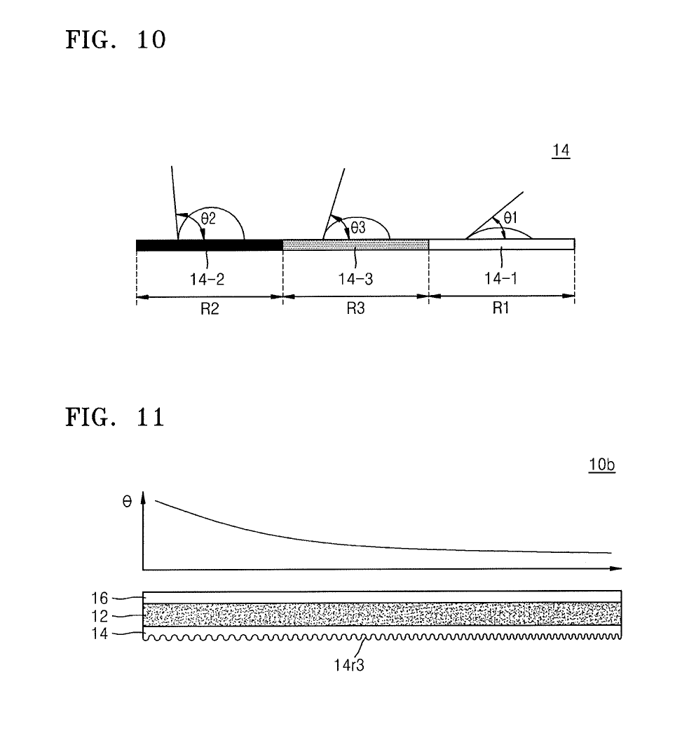

FIG. 10 is a diagram for comparing contact angles in regions of a resin release layer 14 included in a release film for controlling a flow of resin, according to an exemplary embodiment.

Referring to FIG. 10, the resin release layer 14 may include the first region R1 and the second region R2, like the resin release layer 14 shown in FIGS. 1 to 4. A part of the first region R1 of the resin release layer 14 may be the first part 14-1, and a part of the second region R2 of the resin release layer 14 may be the second part 14-2.

The first part 14-1 may have a first contact angle θ1 at a surface thereof. The second part 14-2 may have a second contact angle θ2 at a surface thereof. The second contact angle θ2 may be larger than the first contact angle θ1. For example, the first part 14-1 may have a water contact angle of about 50 degrees or less at a surface thereof, and the second part 14-2 may have a water contact angle of about 90 degrees or more at a surface thereof.

For example, the first part 14-1 and the second part 14-2 may be formed of different materials so as to have different contact angles at their surfaces. In another example, different material layers may be formed, respectively, on an exposed surface of the first part 14-1 and an exposed surface of the second part 14-2 so that the first part 14-1 and the second part 14-2 have different contact angles at their surfaces. For example, as shown in FIG. 2, the second resin release layer 14b may be formed on the second region R2 of the first resin release layer 14a formed in all the first and second regions R1 and R2. As another example, as shown in FIG. 3, the first resin release layer 14a may be formed on the first region R1 of the second resin release layer 14b formed in all the first and second regions R1 and R2. The average roughness of the surface of the first part 14-1 may be different from that of the surface of the second part 14-2 so that a contact angle of the surface of the first part 14-1 is different from that of the surface of the second part 14-2. For example, as shown in FIG. 4, the uneven portion 14r may be formed only in a surface of the second region R2 of the resin release layer 14 formed in all the first and second regions R1 and R2.

The resin release layer 14 may further include a third region R3, like the resin release layer 14 shown in FIGS. 5 to 9. The third region R3 of the resin release layer 14 may be a third part 14-3. The third part 14-3 may have a third contact angle θ3 at a surface thereof. For example, the third part 14-3 may have a water contact angle of about 60 degrees to about 80 degrees at a surface thereof.

For example, the third part 14-3 may be formed of a material that is different from those of the first and second parts 14-1 and 14-2 so that a contact angle of the surface of the third part 14-3 is different from those of the surfaces of the first and second parts 14-1 and 14-2. In another example, a material layer that is different from a material layer that is formed on exposed surfaces of the first and second parts 14-1 and 14-2 may be formed on an exposed surface of the third part 14-3 so that a contact angle of the surface of the third part 14-3 is different from those of the surfaces of the first and second parts 14-1 and 14-2. For example, as shown in FIG. 6, the third resin release layer 14c may be formed on the third region R3 of the first resin release layer 14a formed in all the first and second regions R1 and R2. The average roughness of the surface of the first part 14-1 may be different from that of the surface of the second part 14-2 so that a contact angle of the surface of the first part 14-1 is different from that of the surface of the second part 14-2. For example, as shown in FIGS. 7 and 8, the uneven portion 14r may be formed only in a surface of the third region R3 of the first resin release layer 14a. As another example, as shown in FIG. 9, the first uneven portion 14r1 and the second uneven portion 14r2, which have different roughness values, may be respectively formed in a surface of the second region R2 and a surface of the third region R3 of the resin release layer 14 formed in all the first, second, and third regions R1, R2, and R3.

FIG. 11 is a diagram illustrating a change in a contact angle according to the position of a resin release layer included in a release film 10b for controlling a flow of resin, according to an exemplary embodiment.

Referring to FIG. 11, the release film 10b may include the backbone layer 12, a resin release layer 14 attached to the first surface of the backbone layer 12, and the mold release layer 16 attached to the second surface of the backbone layer 12.

The surface roughness of the first surface 14′ of the resin release layer 14, which faces away from the backbone layer 12, may have a gradient. An uneven portion 14r3 having a decreasing size in one direction may be formed in the first surface 14′ of the resin release layer 14, which faces away from the backbone layer 12. In FIG. 11, although the size of the uneven portion 14r3 is reduced, embodiments are not limited thereto. For example, the size of the uneven portion 14r3 may be increased or decreased, and may be increased or decreased only in a part of the first surface 14′ of the resin release layer 14, which faces away from the backbone layer 12.

In this case, the whole surface or part of the surface of the resin release layer 14 which faces away from the backbone layer 12, may have a contact angle θ having a gradient. For example, in the surface of the resin release layer 14, which faces away from the backbone layer 12, the contact angle θ may be reduced in one direction. In FIG. 11, although the contact angle θ is reduced in one direction, embodiments are not limited thereto. For example, the contact angle θ may be increased or decreased, and may be increased or decreased only in a part of the surface of the resin release layer 14, which faces away from the backbone layer 12.

The release film 10b illustrated in FIG. 11 may be applied to a part of each of the release films 10, 10-1, 10-2, 10-3, 10a, 10a-1, 10a-2, 10a-3, and 10a-4 illustrated in FIGS. 1 to 9. For example, the release film 10b shown in FIG. 11 may be disposed between the first region R1 and the second region R2, between the second region R2 and the third region R3, and/or between the first region R1 and the third region R3 in the release films 10, 10-1, 10-2, 10-3, 10a, 10a-1, 10a-2, 10a-3, and 10a-4 illustrated in FIGS. 1 to 9, or may be disposed to have a region that is independent of the first through third regions R1, R2, and R3.

FIG. 12 is a cross-sectional view illustrating a method of manufacturing a semiconductor package, according to an exemplary embodiment.

Referring to FIG. 12 together with FIGS. 1 to 9 and 11, a mold 1 having a cavity surface 1C that defines a cavity CV is prepared. The release film 10 is attached to the cavity surface 1C of the mold 1. It is noted, however, that any of the release films 10, 10-1, 10-2, 10-3, 10a, 10a-1, 10a-2, 10a-3, 10a-4, and 10b illustrated in FIGS. 1 to 9 and 11 and a combination thereof may be applied as the release film 10 shown in FIG. 12. The release film 10 may be attached to the cavity surface 1C of the mold 1, so that the mold release layer 16 faces the cavity surface 1C of the mold 1.

A semiconductor chip 100 attached on a package base substrate 200 is accommodated in the cavity CV. The package base substrate 200 may be, e.g., a printed circuit board (PCB), a ceramic substrate, or an interposer.

When the package base substrate 200 is a PCB, the package base substrate 200 may include a substrate base, an upper pad formed on an upper surface of the substrate base, and a lower pad formed on a lower surface of the substrate base. The upper pad and the lower pad may be exposed by a solder-resist layer that covers the upper surface and the lower surface of the substrate base. The substrate base may be formed of at least one of a phenol resin, an epoxy resin, and a polyimide. For example, the substrate base may include at least one of a frame retardant 4 (FR4), a tetrafunctional epoxy, a polyphenylene ether, an epoxy/polyphenylene oxide, a bismaleimide triazine, a thermount, cyanate ester, a polyimide, and a liquid crystal polymer. The upper pad and the lower pad may be formed of, e.g., copper, nickel, stainless steel, or beryllium copper. An internal wire that electrically connects the upper pad to the lower pad may be formed inside the substrate base. The upper pad and the lower pad may be parts exposed by the solder-resist layer from among circuit wires patterned after coating a copper (Cu) foil on the upper and lower surfaces of the substrate base.

When the package base substrate 200 is an interposer, the package base substrate 200 may include a substrate base formed of a semiconductor material, an upper pad formed on an upper surface of the substrate base, and a lower pad formed on a lower surface of the substrate base. The substrate base may be formed from, e.g., a silicon wafer. An internal wire may be formed in the upper surface, the lower surface, or the inside of the substrate base. In addition, a through-via that electrically connects the upper pad to the lower pad may be formed inside the substrate base.

The semiconductor chip 100 may be attached on the package base substrate 200 by using a flip-chip method. The semiconductor chip 100 may be attached on the package base substrate 200 so that an internal connection terminal 110 formed on an active surface corresponds to the upper pad of the package base substrate 200. The internal connection terminal 110 may be, e.g., a solder ball or a bump. The semiconductor package to be formed may be a molded under-fill package in which a space between the package base substrate 200 and the semiconductor chip 100 is filled with resin for forming an encapsulant without separately forming an under-fill material for filling the space between the package base substrate 200 and the semiconductor chip 100.

For example, a semiconductor substrate used to form the semiconductor chip 100 may include silicon (Si). In another example, the semiconductor substrate used to form the semiconductor chip 100 may include a semiconductor element. e.g., germanium (Ge), or a compound semiconductor, e.g., silicon carbide (SiC), gallium arsenide (GaAs), indium arsenide (InAs), and indium phosphide (InP). The semiconductor substrate used to form the semiconductor chip 100 may have a silicon on insulator (SOI) structure. For example, the semiconductor substrate may include a buried oxide (BOX) layer. The semiconductor substrate may include a conductive region, for example, a well doped with impurities. The semiconductor substrate may have various isolation structures, such as a shallow trench isolation (STI) structure.

The semiconductor chip 100 may include a semiconductor device including various types of individual devices. The individual devices may include various microelectronic devices, e.g., a metal-oxide-semiconductor field effect transistor (MOSFET) (e.g., a complementary metal-oxide-semiconductor (CMOS) transistor), a system large scale integration (LSI) device, an image sensor (e.g., a CMOS imaging sensor (CIS)), a light-emitting device (e.g., a light-emitting diode (LED)), a micro-electro-mechanical system (MEMS) component, an active device, and a passive device. The individual devices may be electrically connected to the conductive region of the semiconductor substrate used to form the semiconductor chip 100. The semiconductor device may further include a conductive wire or a conductive plug that electrically connects at least two of the individual devices to each other or electrically connects the individual devices to the conductive region of the semiconductor substrate used to form the first semiconductor chip 100. The individual devices may be electrically separated from their adjacent individual devices by insulation layers, respectively.

The semiconductor chip 100 may be a memory semiconductor chip or a logic semiconductor chip. The semiconductor chip 100 may be, e.g., a processor unit, such as a microprocessor unit (MPU) or a graphics processor unit (GPU). The semiconductor chip 100 may be, e.g., a volatile memory semiconductor chip, such as Dynamic Random Access Memory (DRAM) or Static Random Access Memory (SRAM), or a non-volatile memory semiconductor chip, such as Phase-change Random Access Memory (PRAM), Magnetoresistive Random Access Memory (MRAM), Ferroelectric Random Access Memory (FeRAM), or Resistive Random Access Memory (RRAM).

The semiconductor chip 100 may include a plurality of individual semiconductor chips that are sequentially stacked. In this case, the plurality of individual semiconductor chips may be stacked in a vertical direction. A semiconductor substrate used to form each of the plurality of individual semiconductor chips included in the semiconductor chip 100, and a semiconductor device formed in each of the plurality of individual semiconductor chips are similar to the semiconductor substrate and the semiconductor device for the semiconductor chip 100, and thus detailed descriptions thereof will be omitted. In each of the plurality of individual semiconductor chips included in the semiconductor chip 100, an active surface may face the package base substrate 200.

When the semiconductor chip 100 includes a plurality of individual semiconductor chips, at least some of the plurality of individual semiconductor chips may include a plurality of penetrating electrodes. The plurality of individual semiconductor chips may be electrically connected to each other by their corresponding penetrating electrodes, and may be electrically connected to the package base substrate 200. Signals for the plurality of penetrating electrodes, a power supply voltage, and a ground voltage may be provided.

The penetrating electrodes may be implemented by using through-silicon vias (TSVs). Each of the penetrating electrodes may include a metal wiring layer and a metal barrier layer that surrounds the metal wiring layer. The metal wiring layer may include, e.g., Cu or W. For example, the metal wiring layer may be formed of Cu, CuSn, CuMg, CuNi, CuZn, CuPd, CuAu, CuRe, CuW, W, or a W alloy, but embodiments are not limited thereto. For example, the metal wiring layer may include one or more of Al, Au, Be, Bi, Co, Cu, Hf, In, Mn, Mo, Ni, Pb, Pd, Pt, Rh, Re, Ru, Ta, Te, Ti, W, Zn, and Zr, and may have a stacked structure in which the selected one or more material is stacked. The metal barrier layer may include at least one of W, WN, WC, Ti, TiN, Ta, TaN, Ru, Co, Mn, WN, Ni, and NiB, and may be a single layer or multiple layers. A spacer insulation layer may be interposed between the penetrating electrodes and a semiconductor substrate used to form each of the individual semiconductor chips. The spacer insulation layer may be formed as an oxide layer, a nitride layer, a carbide layer, a polymer, or a combination thereof. The spacer insulation layer may be formed as an ozone/tetra-ethyl ortho-silicate (O₃/TEOS)-based high aspect ratio process (HARP) oxide layer formed by sub-atmospheric CVD.

An upper surface of the semiconductor chip 100 accommodated in the cavity CV may contact the release film 10. In other words, the upper surface of the semiconductor chip 100 accommodated in the cavity CV may contact the resin release layer 14. When the upper surface of the semiconductor chip 100 accommodated in the cavity CV contacts the release film 10, a semiconductor package to be formed may be an exposed MUF (eMUF) package.

Next, resin is injected into the cavity CV. The resin may be formed of, e.g., Epoxy Mold Compound (EMC). The resin may be an epoxy-based material mixed with filler particles, e.g., silica or alumina particles.

An area through which the resin may pass in a surface perpendicular to a resin injection direction may be relatively large in a space S2, i.e., where there is no semiconductor chip, as compared to a space S1, i.e., where the semiconductor chip 100 is positioned. Accordingly, if a release film on a mold 1 did not control a flow of a resin, a flow of the resin injected into the second space S2 (where there is no semiconductor chip) could be relatively fast, and a flow of the resin injected into the first space S1 (where the semiconductor chip 100 is positioned) could be relatively slow. In contrast, since the release film 10 according to example embodiments controls the flow of the resin, an average flow of the resin may be controlled to be constant both in the first space S1 (where the semiconductor chip 100 is positioned) and in the second space S2 (where there is no semiconductor chip). Accordingly, a void may be prevented from occurring in an encapsulant for encapsulating the semiconductor package, and thus, the reliability of the semiconductor package may be improved. A resin flow control will be described below with reference to FIGS. 14 to 17.

After forming the encapsulant by injecting the resin to the cavity CV, the encapsulated semiconductor chip 100 may be separated from the release film 10 to thereby form the semiconductor package. In addition, when the release film 10 is separated from the mold 1, the mold 1 may be prevented from being contaminated and may be reused, and the durability of the mold 1 may be increased. Accordingly, the release film 10 may improve the reliability of the semiconductor package and reduce the manufacturing cost of the semiconductor package.

When a plurality of semiconductor chips 100 are accommodated in the cavity CV to form a plurality of semiconductor packages, the plurality of semiconductor chips 100 encapsulated with an encapsulant using a resin separated from the release film 10 may be separated as individual semiconductor packages.

In FIG. 12, although the package base substrate 200 is accommodated in the cavity CV along with the semiconductor chip 100, embodiments are not limited thereto. For example, the mold 1 may be disposed on the package base substrate 200, and the package base substrate 200 may not be accommodated in the cavity CV.

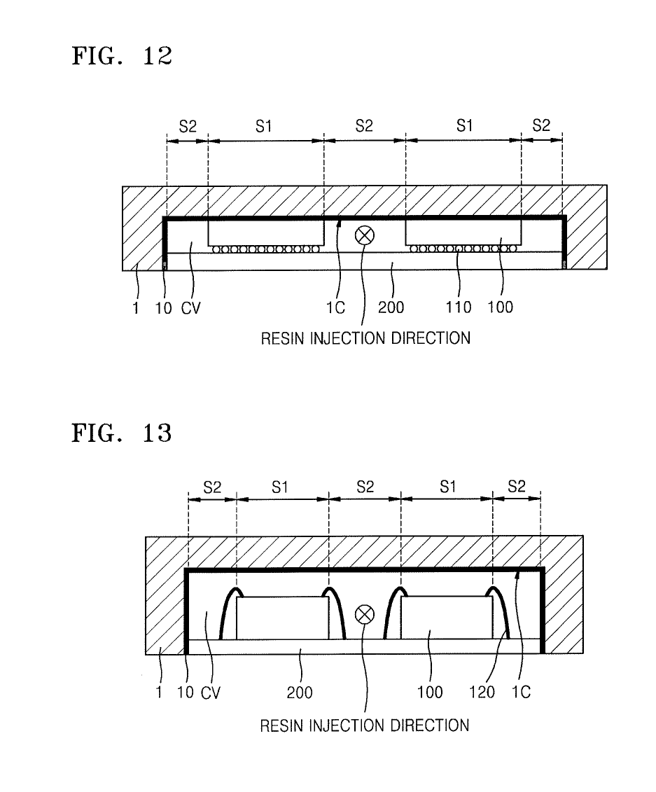

FIG. 13 is a cross-sectional view illustrating a method of manufacturing a semiconductor package, according to another exemplary embodiment. Descriptions overlapping with the descriptions of FIG. 12 are omitted.

Referring to FIG. 13, the mold 1 having the cavity surface 1C that defines the cavity CV is prepared. The release film 10 is attached to the cavity surface 1C of the mold 1. The semiconductor chip 100 attached on the package base substrate 200 is accommodated in the cavity CV.

An upper surface of the semiconductor chip 100 accommodated in the cavity CV may be separate from the release film 10. In other words, the upper surface of the semiconductor chip 100 accommodated in the cavity CV may be separated, i.e., spaced apart, from the resin release layer 14.

The semiconductor chip 100 may be electrically connected to a package base substrate 200 by using a wire bonding method using a bonding wire 120. The semiconductor chip 100 may be attached on the package base substrate 200 so that a non-active surface faces the package base substrate 200. The semiconductor chip 100 may be attached on the package base substrate 200 by using a die attach film (DAF) attached to the non-active surface. Alternatively, the semiconductor chip 100 may be attached on the package base substrate 200 by using a flip-chip method, as shown in FIG. 12.

Next, resin is injected into the cavity CV. An area through which the resin may pass in a surface perpendicular to a resin injection direction may be relatively large in a space where there is no semiconductor chip, compared to a space where the semiconductor chip 100 is positioned. When an interval between the upper surface of the semiconductor chip 100 and a release film is sufficiently large, a flow of the resin may be substantially uniform regardless of the presence of the semiconductor chip 100. However, as the interval between the upper surface of the semiconductor chip 100 and a release film has to be minimized to minimize the volume of a semiconductor package to be formed, if a release film does not control a flow of the resin, a flow of the resin that is injected into a second space S2 may be relatively faster than the flow of the resin injected into the first space S1. In contrast, since the release film 10 according to example embodiments controls the flow of the resin, an average flow of the resin may be controlled to be constant in the first space S1, where there is the semiconductor chip 100, and in the second space S2, where there is no semiconductor chip. Accordingly, an encapsulant for encapsulating the semiconductor package may be uniformly formed, and thus, the reliability of the semiconductor package may be improved. A resin flow control will be described below with reference to FIGS. 14 to 17.

After forming the encapsulant by injecting the resin to the cavity CV, the semiconductor chip 100 encapsulated with the resin may be separated from the release film 10 to thereby form the semiconductor package. In addition, after the release film 10 is separated from the mold 1, the mold 1 may be reused. Accordingly, the release film 10 may improve the reliability of the semiconductor package and prevent the mold 1 from being contaminated by the resin.

When a plurality of semiconductor chips 100 are accommodated in the cavity CV to form a plurality of semiconductor packages, the plurality of semiconductor chips 100 encapsulated with a resin separated from the release film 10 may be separated as individual semiconductor packages.

FIG. 14 is a plan view of a resin release layer 14 included in the release film 10 for controlling a flow of resin, according to an exemplary embodiment.

Referring to FIG. 14, the release film 10 includes the resin release layer 14 including the first part 14-1 and the second part 14-2. The first part 14-1 of the resin release layer 14 is a part of the resin release layer 14 in the first region R1 shown in FIGS. 1 to 4. The second part 14-2 of the resin release layer 14 is the part of the resin release layer 14 in the second region R2 shown in FIGS. 1 to 4.

FIG. 14 is a plan view of the release film 10 at the resin release layer 14, and illustrates the first surface 14′, i.e., the resin flow control surface 14′, of the resin release layer 14 which faces away from the backbone layer 12, in FIGS. 1 to 4. Accordingly, unless stated otherwise, each of the first and second parts 14-1 and 14-2 of the resin release layer 14 illustrated in FIG. 14 may denote a part of a resin flow control surface of the resin release layer 14 in the first and second regions R1 and R2 illustrated in FIGS. 1 to 4.

A contact angle in the first part 14-1 of the release film 10 may be different from that in the second part 14-2 of the release film 10. For example, the contact angle in the second part 14-2 may be larger than that in the first part 14-1.

The first part 14-1 and the second part 14-2 may be alternately disposed in a resin injection direction. The second part 14-2 may have a plurality of linear stripe shapes that extend in a direction (a horizontal direction in FIG. 4) perpendicular to the resin injection direction and are parallel to each other.

When resin is injected in the resin injection direction in a state in which a semiconductor chip 100 is disposed to contact the release film 10 or to be adjacent to the release film 10, a flow of the resin may be relatively slow in the first space S1 (where the semiconductor chip 100 is disposed) in the resin injection direction, and a flow of the resin may be relatively fast in a second space S2 (where the semiconductor chip 100 is not disposed) in the resin injection direction. In other words, when resin is injected in the resin injection direction (along the arrow direction in FIG. 14), the resin flow in the second space S2 is faster than in the first space S1 due to the semiconductor chips 100 (dashed line in FIG. 14) in the first space S1, so the resin may flow through the first part 14-1 and reach the second part 14-2 in the second space S2 faster than in the first space S1.

However, according to example embodiments, as the second part 14-2 has a larger contact angle than the first part 14-1, resin flow in the second part 14-2 is slower than in the first part 14-1. Therefore, the resin may be completely spread in the first part 14-1 of the second space S2 before proceeding to the second part 14-2. In other words, the second part 14-2 having a larger contact angle that the first part 14-1 may function as a barrier to a flow of the resin, so after the resin reaches all parts of a boundary between the first part 14-1 and the second part 14-2, the resin may proceed to the second part 14-2.

If the release film 10 did not control the flow of the resin, a resin proceeding through the second space S2 (where a flow of the resin is relatively fast) could be spread to completely cover the second space S2 and parts of the first space S1 (in which the semiconductor chip 100 is not disposed), while resin proceeding through the first space S1 (where a flow of the resin is relatively slow) could leave parts unfilled (e.g., where the semiconductor chip 100 is disposed). As such, voids could be formed in the first space S1 due to the uneven resin flow distribution. However, since the release film 10 according to example embodiments may control, e.g., selectively adjust according to position of the semiconductor chip 100, the flow of the resin, the release film 10 may prevent or substantially minimize occurrence of voids.

In addition, the semiconductor chip 100 may be disposed to intersect at least one linear stripe shape of the second part 14-2. That is, if the semiconductor chip 100 does not intersect any linear stripe shapes of the second part 14-2, when a speed difference between a flow of the resin in the first space S1 and a flow of the resin in the second space S2 is relatively large, a flow of the resin may occur in a direction opposite to the resin injection direction through the second space S2 before the resin completely fills the first space S1 where the semiconductor chip 100 is disposed. Thus, a void may occur in the first space S1 where the semiconductor chip 100 is disposed. However, when the semiconductor chip 100 is disposed to intersect at least one second part 14-2 according to example embodiments, a flow of the resin does not occur in the direction opposite to the resin injection direction, and thus, a void may be prevented from occurring.

In FIG. 14, although the first part 14-1 and the second part 14-2 have linear stripe shapes, and the width of the linear stripe shape of the first part 14-1 is similar to that of the linear stripe shape of the second part 14-2, embodiments are not limited thereto. For example, the first part 14-1 may have a linear stripe shape having a width that is larger than that of the linear stripe shape of the second part 14-2.

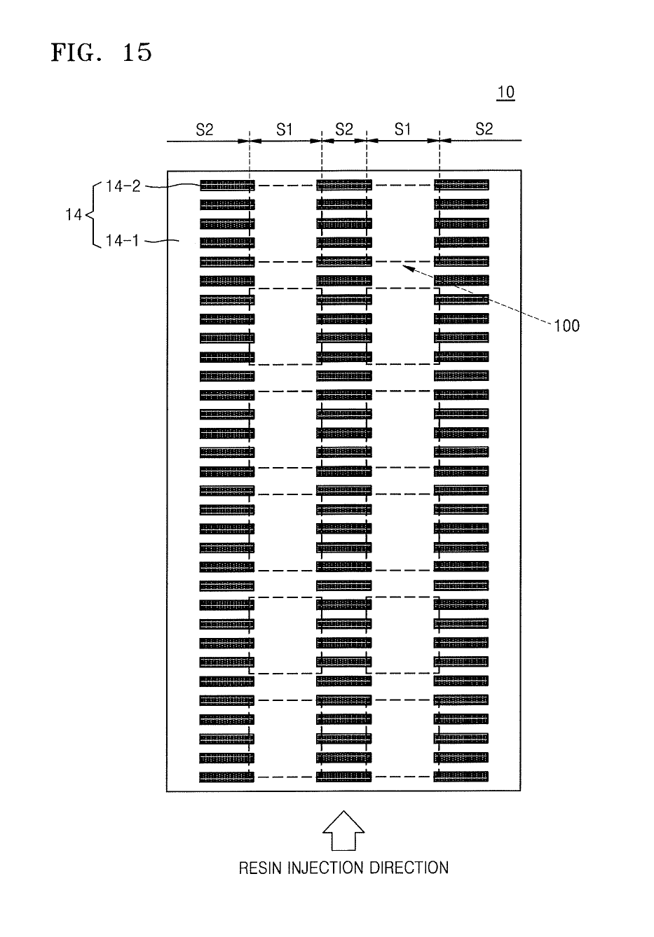

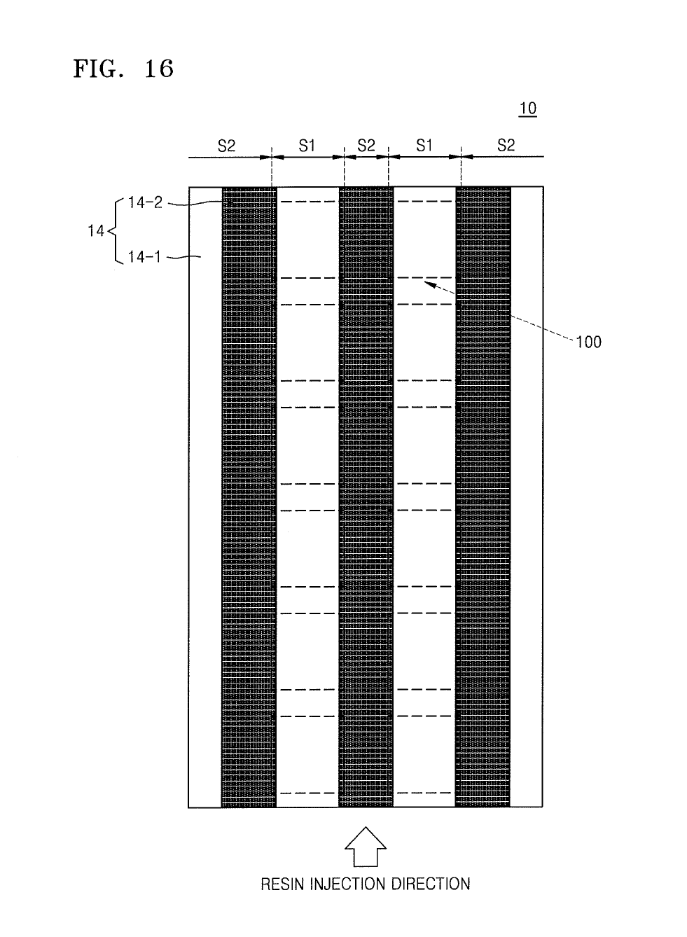

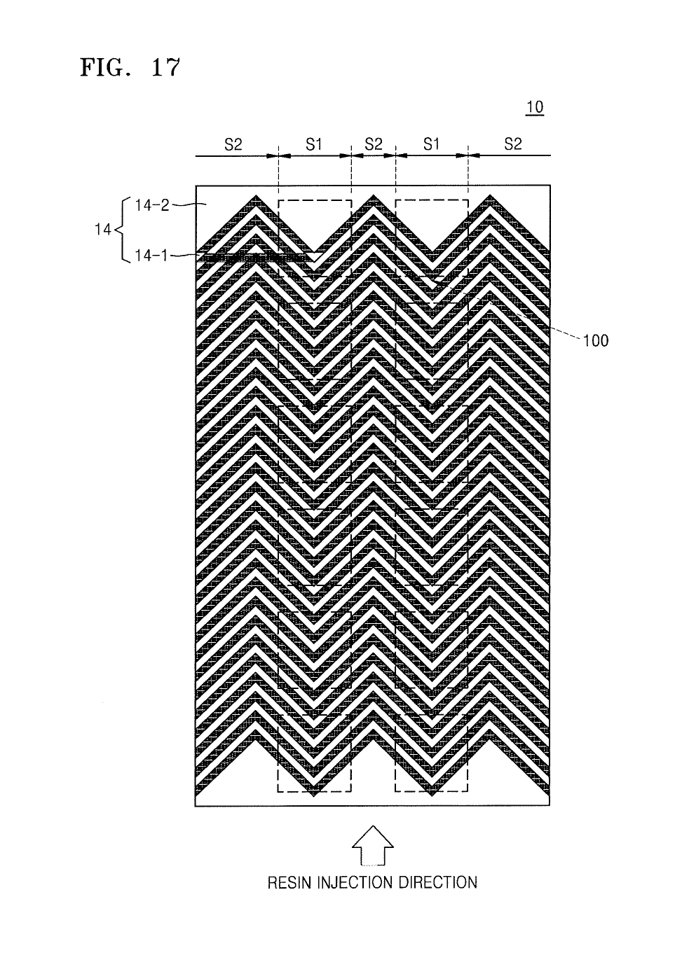

FIG. 15 is a plan view of a resin release layer 14 included in a release film 10 for controlling a flow of resin, according to another exemplary embodiment. Among descriptions of FIG. 15, a description overlapping with a description of FIG. 14 may be omitted.

Referring to FIG. 15, the release film 10 includes the resin release layer 14 including the first part 14-1 and the second part 14-2. A contact angle in the first part 14-1 of the release film 10 may be different from that in the second part 14-2 of the release film 10. For example, the contact angle in the second part 14-2 may be larger than that in the first part 14-1.

The second part 14-2 may have a plurality of bar shapes that are arranged in a matrix form. The second part 14-2 may have a plurality of bar shapes that have a short axis in a resin injection direction and a long axis in a direction (a horizontal direction in FIG. 15) perpendicular to the resin injection direction. Accordingly, the area of the second part 14-2 may be smaller than that of the first part 14-1.

The second part 14-2 may be repeatedly arranged along the second space S2 in which a semiconductor chip 100 is not disposed in the resin injection direction. The second part 14-2 may completely cross the second space S2 where the semiconductor chip 100 is not disposed in the resin injection direction. However, the second part 14-2 may have a long axis length that does not cross at least a part of the first space S1 where the semiconductor chip 100 is disposed in the resin injection direction. In other words, the second part 14-2 may have a long axis length that extends from the second space S2, in which the semiconductor chip 100 is not disposed, up to a part of the first space S1 in which the semiconductor chip 100 is disposed.

A flow of the resin may be relatively slow in the first space S1 where the semiconductor chip 100 is disposed, and a flow of the resin may be relatively fast in the second space S2 where the semiconductor chip 100 is not disposed. Accordingly, in the second space S2 in which a flow of the resin is relatively fast, the second part 14-2 functions as a barrier to a flow of the resin, i.e., the second part 14-2 slow down the flow in the second space S2. Thus, some of the resin may be spread to the first space S1 in which the semiconductor chip 100 is disposed in the resin injection direction. Accordingly, in the first space S1 in which a flow of the resin is relatively slow, a flow of the resin in the resin injection direction encounters a resin spreading from the second space S2 to the first space S1, and thus, the occurrence of a void may be prevented.

In FIG. 15, although in a short axis direction of the second part 14-2 (i.e., the resin injection direction), an interval between the second part 14-2 and an adjacent second part 14-2 is similar to an interval between the second part 14-2 and another adjacent second part 14-2, embodiments are not limited thereto. For example, in the resin injection direction, an interval between two adjacent second parts 14-2 may be larger than that of the second part 14-2.

FIG. 16 is a plan view of a resin release layer 14 included in a release film 10 for controlling a flow of resin, according to another exemplary embodiment. Among descriptions of FIG. 16, a description overlapping with a description of FIG. 14 may be omitted.

Referring to FIG. 16, the release film 10 includes the resin release layer 14 including the first part 14-1 and the second part 14-2. A contact angle in the first part 14-1 of the release film 10 may be different from that in the second part 14-2 of the release film 10. For example, the contact angle in the second part 14-2 may be larger than that in the first part 14-1. In this case, a flow of resin may be faster in the first part 14-1 than in the second part 14-2.

The first part 14-1 and the second part 14-2 may be alternately disposed in a direction (a horizontal direction in FIG. 16) perpendicular to a resin injection direction. The second part 14-2 may have a plurality of linear stripe shapes that extend in the resin injection direction and are parallel to each other. The second part 14-2 may be arranged to extend along the second space S2 where the semiconductor chip 100 is not disposed in the resin injection direction.

If the release film 10 were not controlling a flow of resin, a flow of the resin could be relatively slow in the first space S1 where the semiconductor chip 100 is disposed in the resin injection direction, and could be relatively fast in the second space S2 where the semiconductor chip 100 is not disposed in the resin injection direction. However, as the release film 10 according to embodiments includes the second part 14-2 with a larger contact angle, the flow of the resin in the second space S2 is slowed down by the second part 14-2 in the resin injection direction, and thus, the speed of a flow of the resin in the second part 14-2 may be controlled to be similar to that of a flow of the resin in the first part 14-1. Thus, the occurrence of a void may be prevented or substantially minimized.

As illustrated in FIG. 16, the second part 14-2 may entirely overlap the second space S2 where the semiconductor chip 100 is not disposed. In other words, the second part 14-2 may have a width that is equal to or greater than a distance between two semiconductor chips 100 adjacent to each other in a direction perpendicular to the resin injection direction. A part of the semiconductor chip 100 may overlap the second part 14-2. Since a flow of the resin becomes slower in a region in which a part of the semiconductor chip 100 overlaps the second part 14-2, it is possible to minimize the spreading of the resin to the first part 14-1 via the second part 14-2 even though a flow of the resin in the second part 14-2 is relatively fast, and thus, the occurrence of a void may be prevented.

FIG. 17 is a plan view of a resin release layer 14 included in a release film 10 for controlling a flow of resin, according to another exemplary embodiment. Among descriptions of FIG. 17, a description overlapping with a description of FIG. 14 may be omitted.

Referring to FIG. 17, the release film 10 includes the resin release layer 14 including the first part 14-1 and the second part 14-2. A contact angle in the first part 14-1 of the release film 10 may be different from that in the second part 14-2 of the release film 10. For example, the contact angle in the second part 14-2 may be larger than that in the first part 14-1.

The first part 14-1 and the second part 14-2 may be alternately disposed in a resin injection direction. The second part 14-2 may have a plurality of chevron stripe shapes that are repeatedly arranged. The second part 14-2 may function as a barrier to a flow of resin. Since the second part 14-2 has the chevron stripe shapes, the second part 14-2 may allow the resin to spread from the second space S2, in which a semiconductor chip 10 is not disposed, to the first space S1 in which the semiconductor chip 10 is disposed. The resin may be supplied in a direction, which is different from the resin injection direction, along a boundary between the first part 14-1 and the second part 14-2 from the second space S2, in which the semiconductor chip 10 is not disposed, to the first space S1 in which the semiconductor chip 10 is disposed. A flow of the resin which is relatively slow in the first space S1 may meet a resin supplied in a direction, which is different from the resin injection direction, along a boundary between the first part 14-1 and the second part 14-2, and thus, the occurrence of a void may be prevented.

An angle between an oblique line of each of the chevron stripe shapes and the resin injection direction may be, for example, 30 degrees through 60 degrees. The angle may be determined by taking into account a difference of a resin flow speed between the first space S1 and the second space S2.

As described above with reference to FIGS. 14 to 17, the release film 10 according to the exemplary embodiments may control a flow of resin so that the occurrence of a void is prevented. Accordingly, defects of the semiconductor package may be prevented even though a volume of an encapsulant is minimized, and thus, the semiconductor package may be miniaturized.

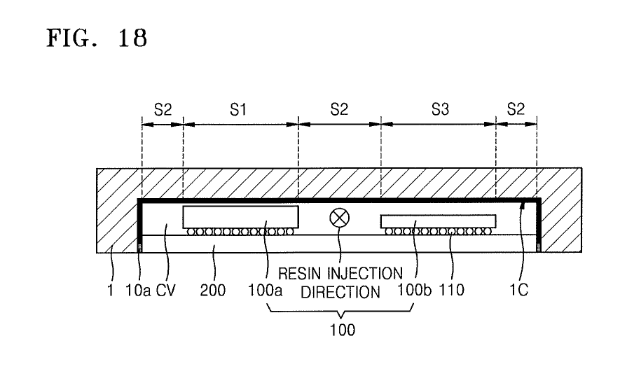

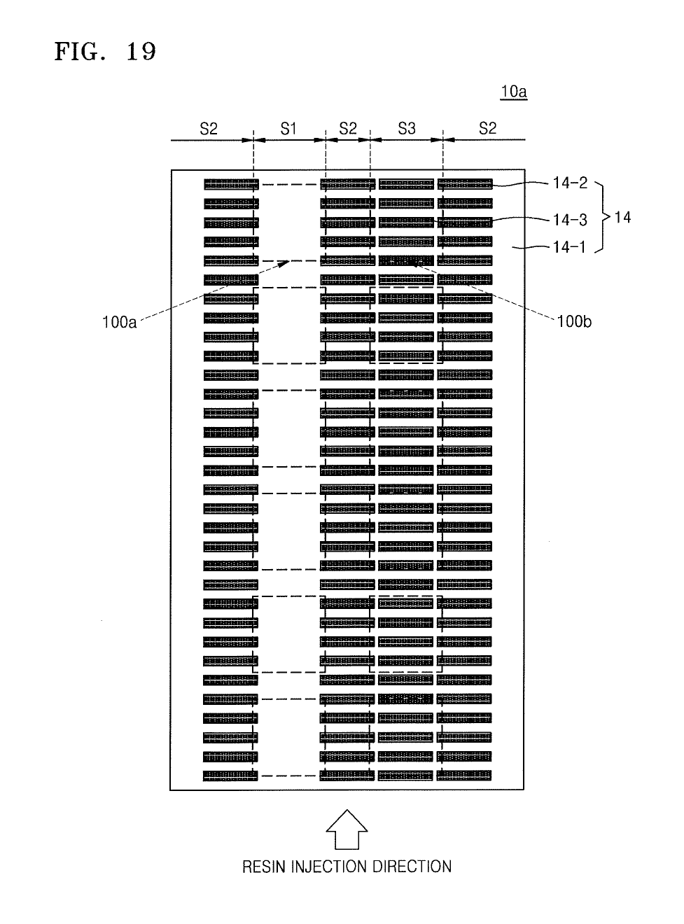

FIG. 18 is a cross-sectional view illustrating a method of manufacturing a semiconductor package, according to another exemplary embodiment. Among descriptions of FIG. 18, descriptions overlapping with descriptions of FIGS. 12 and 13 may be omitted.

Referring to FIG. 18, the mold 1 having the cavity surface 1C for defining the cavity CV is prepared, and the release film 10 is attached to the cavity surface 1C of the mold 1. A semiconductor chip 100b attached on a package base substrate 200 is accommodated in the cavity CV. The semiconductor chip 100 may include a first semiconductor chip 100a and a second semiconductor chip 100b. Upper surfaces of the first semiconductor chip 100a and the second semiconductor chip 100b may be at different levels with respect to a main surface of the package base substrate 200. For example, the first semiconductor chip 100a may have an upper surface having a higher level than an upper surface of the second semiconductor chip 100b. Accordingly, an interval between the upper surface of the first semiconductor chip 100a and the release film 10 may be smaller than that between the upper surface of the second semiconductor chip 100b and the release film 10.

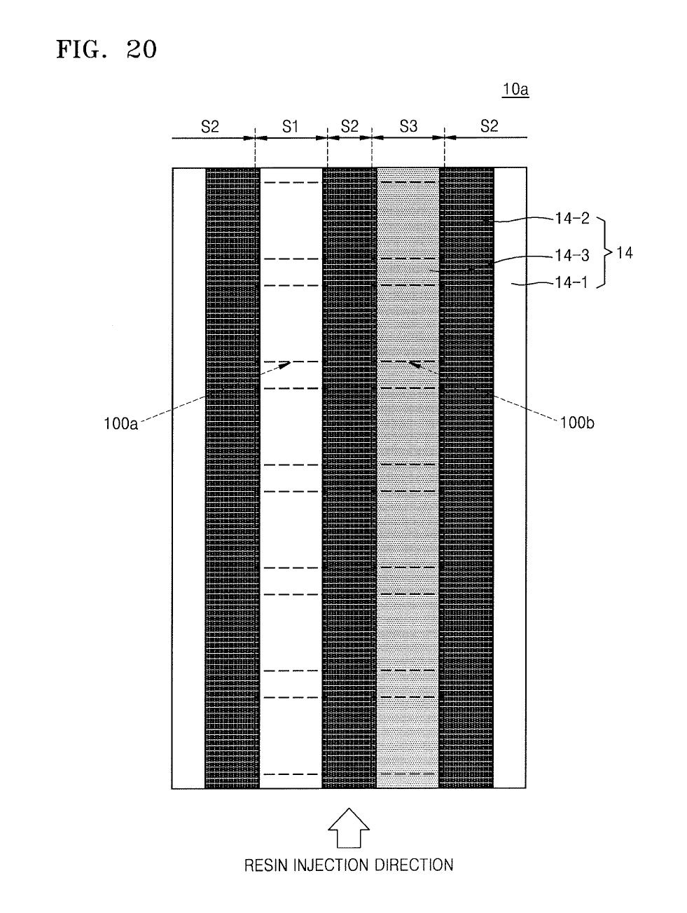

As such, when the release film 10 does not control a flow of resin, a flow of the resin that is injected into a third space S3 with the second semiconductor chip 100b may be relatively fast, and a flow of the resin that is injected into the first space S1 with the first semiconductor chip 100a may be relatively slow. However, since the release film 10 doe control the flow of the resin, an average flow of the resin may be controlled to be constant in the first space S1 with the first semiconductor chip 100a and in the third space S3 with the second semiconductor chip 100b. In addition, an average flow of the resin may be controlled to be constant in the first and third spaces S1 and S3 (with the first and second semiconductor chips 100a and 100b) and in the second space S2 where there is no semiconductor chip. Accordingly, a void may be prevented from occurring in an encapsulant for encapsulating the semiconductor package, and thus, the reliability of the semiconductor package may be improved. A resin flow control will be described below with reference to FIGS. 19 and 20.

FIG. 19 is a plan view of a resin release layer 14 included in a release film 10a for controlling a flow of resin, according to another exemplary embodiment. Among descriptions of FIG. 19, a description overlapping with a description of FIG. 15 may be omitted.

Referring to FIG. 19, the release film 10a includes the resin release layer 14 including the first part 14-1, the second part 14-2, and a third part 14-3.

The first part 14-1 of the resin release layer 14 may be a part of the resin release layer 14 in the first region R1 shown in FIGS. 5 to 9. The second part 14-2 of the resin release layer 14 may be a part of the resin release layer 14 in the second region R2 shown in FIGS. 5 to 9. The third part 14-3 of the resin release layer 14 may be a part of the resin release layer 14 in the third region R3 shown in FIGS. 5 to 9. A contact angle in the first part 14-1 of the release film 10a may be different from that in the second part 14-2 of the release film 10a. For example, the contact angle in the second part 14-2 may be larger than that in the first part 14-1.

The second part 14-2 may have a plurality of bar shapes that are arranged in a matrix form. The second part 14-2 may have a plurality of bar shapes that have a short axis in a resin injection direction and a long axis in a direction (a horizontal direction in FIG. 19) perpendicular to the resin injection direction. The second part 14-2 may be repeatedly arranged along the second space S2 in which first and second semiconductor chips 100a and 100b are not disposed in the resin injection direction. The second part 14-2 may completely cross the second space S2 where the first and second semiconductor chips 100a and 100b are not disposed. However, the second part 14-2 may have a long axis length that does not cross at least a part of each of first and third spaces S1 and S3 where the first and second semiconductor chips 100a and 100b are disposed, respectively, in the resin injection direction. In other words, the second part 14-2 may have a long axis length that extends from the second space S2, in which the first and second semiconductor chips 100a and 100b are not disposed, up to a part of each of the first and third spaces S1 and S3 in which the first and second semiconductor chips 100a and 100b are disposed, respectively.

The first semiconductor chip 100a may have an upper surface having a higher level than an upper surface of the second semiconductor chip 100b. Accordingly, an interval between the upper surface of the first semiconductor chip 100a and the release film 10a may be smaller than that between the upper surface of the second semiconductor chip 100b and the release film 10a. Accordingly, when the release film 10a does not control a flow of resin, a flow of the resin that is injected into the third space S3 with the second semiconductor chip 100b may be relatively fast, and a flow of the resin that is injected into the first space S1 with the first semiconductor chip 100a may be relatively slow.

The third part 14-3 may have a plurality of bar shapes repeatedly arranged along the third space S3 where the second semiconductor chip 100b is disposed. The third part 14-3 may have a plurality of bar shapes that have a short axis in a resin injection direction and a long axis in a direction (the horizontal direction in FIG. 19) perpendicular to the resin injection direction. A contact angle in the second part 14-2 may be larger than that in the first part 14-1, and an angle in the third part 14-3 may be smaller than that in the second part 14-2 and be larger than that in the first part 14-1.

A flow of the resin in the first space S1 where the first semiconductor chip 100a is disposed may be relatively slower than a flow of the resin in the third space S3 where the second semiconductor chip 100b is disposed. Accordingly, in a region (i.e., the third space S3) in which a flow of the resin is relatively fast, the third part 14-3 may function as a barrier to a flow of the resin. In addition, a flow of the resin in the third space S3, where the second semiconductor chip 100b is disposed, may be relatively slower than a flow of the resin in the second space S2 where the first and second semiconductor chips 100a and 100b are not disposed in the resin injection direction. Thus, in a region (i.e., the second space S2) in which a flow of the resin is relatively fast, the second part 14-2 may perform a function of a larger barrier to a flow of the resin. Accordingly, an average flow of the resin may be controlled to be constant, and thus, a void may be prevented from occurring in an encapsulant for encapsulating the semiconductor package and thus the reliability of the semiconductor package may be improved.

In FIG. 19, although the second part 14-2 and the third part 14-3 have bar shapes separate from each other, embodiments are not limited thereto. For example, the second part 14-2 and the third part 14-3 may have bar shapes that are connected to each other and extend in a long axis direction.

FIG. 20 is a plan view of a resin release layer 14 included in the release film 10a for controlling a flow of resin, according to another exemplary. Among descriptions of FIG. 20, descriptions overlapping with descriptions of FIGS. 16 and 19 may be omitted.

Referring to FIG. 20, the release film 10a includes the resin release layer 14 including the first part 14-1, the second part 14-2, and the third part 14-3. A contact angle in the first part 14-1 of the release film 10a may be different from that in the second part 14-2 of the release film 10a. For example, the contact angle in the second part 14-2 may be larger than that in the first part 14-1.

The second part 14-2 may have a plurality of linear stripe shapes that extend parallel to each other in a resin injection direction. The second part 14-2 may be arranged to extend along the second space S2 where first and second semiconductor chips 100a and 100b are not disposed in the resin injection direction.

In the second space S2, in which the first and second semiconductor chips 100a and 100b are not disposed, and thus a flow of the resin is relatively fast, the second part 14-2 may slow a flow of the resin down. The second part 14-2 may completely overlap the second space S2 where the first and second semiconductor chips 100a and 100b are not disposed. In other words, the second part 14-2 may have a width that is equal to or greater than a distance between the first and second semiconductor chips 100a and 100b adjacent to each other in a direction perpendicular to the resin injection direction. A part of each of the first and second semiconductor chips 100a and 100b may overlap the second part 14-2.

The first semiconductor chip 100a may have an upper surface having a higher level than an upper surface of the second semiconductor chip 100b. Accordingly, an interval between the upper surface of the first semiconductor chip 100a and the release film 10a may be smaller than that between the upper surface of the second semiconductor chip 100b and the release film 10a.

The third part 14-3 may have a linear stripe shape that extends along the third space S3 where the second semiconductor chip 100b is disposed in the resin injection direction. An angle in the second part 14-2 may be larger than that in the first part 14-1, and an angle in the third part 14-3 may be smaller than that in the second part 14-2 and be larger than that in the first part 14-1.

A flow of the resin in the first space S1 where the first semiconductor chip 100a is disposed in the resin injection direction may be relatively slower than a flow of the resin in the third space S3 where the second semiconductor chip 100b is disposed. Accordingly, in a region (i.e., the third space S3) in which a flow of the resin is relatively fast, the third part 14-3 may slow a flow of the resin down. In addition, a flow of the resin in the third space S3 where the second semiconductor chip 100b is disposed may be relatively slower than a flow of the resin in the second space S2 where the first and second semiconductor chips 100a and 100b are not disposed. Accordingly, in a region (i.e., the second space S2) in which a flow of the resin is relatively fast, the second part 14-2 may further slow a flow of the resin down. Accordingly, an average flow of the resin may be controlled to be constant, and thus, a void may be prevented from occurring in an encapsulant for encapsulating the semiconductor package and thus the reliability of the semiconductor package may be improved.

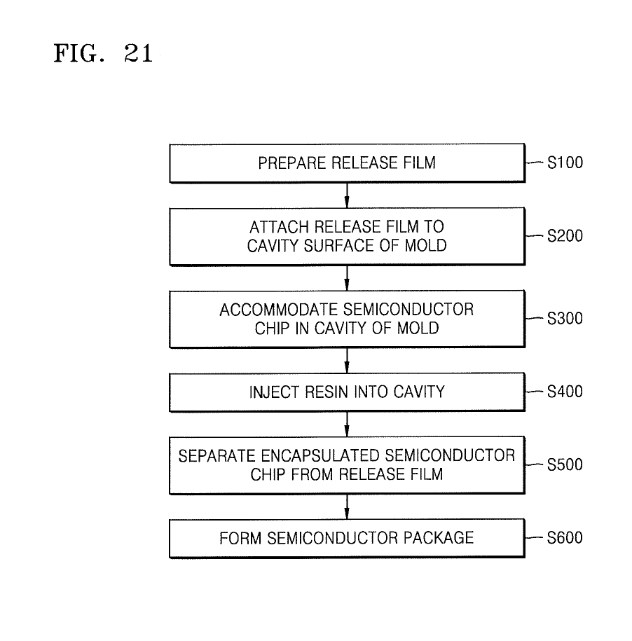

FIG. 21 is a flowchart illustrating a method of manufacturing a semiconductor package, according to an exemplary embodiment. Among descriptions of FIG. 21, descriptions overlapping with descriptions of FIGS. 1 to 20 may be omitted. The reference numerals used in FIGS. 1 to 20 may be cited in descriptions of FIG. 21.

Referring to FIG. 21, a release film is prepared (operation S100). The release film may be one selected from the release films 10, 10-1, 10-2, 10-3, 10a, 10a-1, 10a-2, 10a-3, 10a-4, and 10b illustrated in FIGS. 1 to 9 and 11, the release films 10 and 10a illustrated in FIGS. 14 to 17, 19, and 20, and a combination thereof.

The release film is attached to the cavity surface 1C of the mold 1 (operation S200). The release film may be attached to the cavity surface 1C so that the mold release layer 16 faces the cavity surface 1C.

The semiconductor chip 100 is accommodated in the cavity CV of the mold 1 (operation S300). Resin is injected into the cavity CV of the mold 1 (operation S400). In this case, a flow of the resin may be controlled by the release film so that the occurrence of a void may be prevented.

The semiconductor chip 100 encapsulated with an encapsulant using the resin is separated from the release film (operation S500). In addition, the mold 1 is also separated from the release film. In this case, the encapsulated semiconductor device 100 may be separated first from the release film, the mold 1 may be separated first from the release film, or the encapsulated semiconductor device 100 along with the mold 1 may be separated from the release film.

A semiconductor package is formed through subsequent processes, such as a process of attaching an external connection terminal to the package base substrate 200 and a process of separating semiconductor chips encapsulated with an encapsulant to form individual semiconductor packages (operation S600). In the semiconductor package formed by using the method according to the exemplary embodiment, a step or a difference in unevenness according to regions in the resin release layer 14 of the release film may be transferred to an upper surface of an encapsulant. That is, in the semiconductor package formed by using the method according to the exemplary embodiment, a step or unevenness may be formed in an upper surface of an encapsulant.

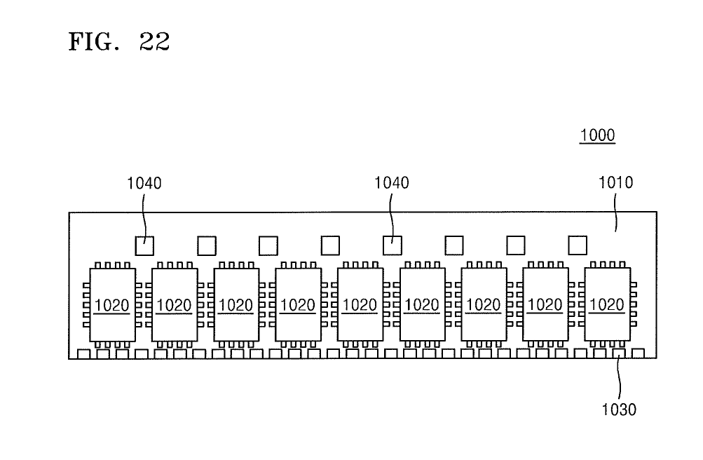

FIG. 22 is a plan view of a memory module 1000 including a semiconductor package according to any one of the exemplary embodiments.

Referring to FIG. 22, the memory module 1000 may include a module substrate 1010 and a plurality of semiconductor packages 1020 attached to the module substrate 1010. Each of the semiconductor packages 1020 includes a semiconductor package manufactured according to any one of the exemplary embodiments.

A connection unit 1030 that may be inserted into a socket of a mother board may be disposed on a side of the module substrate 1010. A passive device, e.g., a ceramic decoupling capacitor 1040, may be disposed on the module substrate 1010. The memory module 1000 is not limited to that illustrated in FIG. 27 and may be manufactured in various ways.

Since the memory module 1000 uses the semiconductor packages 1020 having improved reliability, the memory module 1000 may have high reliability. In addition, since the memory module 1000 uses the semiconductor packages 1020 that may minimize the volume of an encapsulant, the memory module 1000 may have relatively high capacity compared to other memory modules having the same volume as the memory module 1000 and may be miniaturized compared to other memory modules having the same capacity as the memory module 1000.

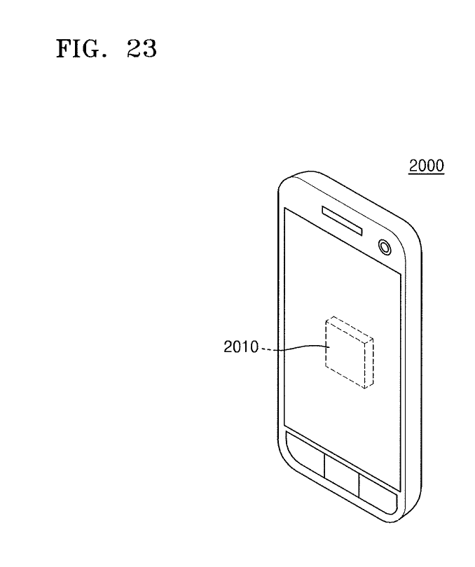

FIG. 23 is a perspective view of an electronic device including a semiconductor package according to any one of the exemplary embodiments.

FIG. 23 illustrates an example in which the electronic device is applied to a mobile phone 2000. The mobile phone 2000 may include a semiconductor package 2010. The semiconductor package 1020 includes a semiconductor package manufactured according to any one of the exemplary embodiments. Since the mobile phone 2000 uses the semiconductor package 2010 that has high reliability and that has relatively high capacity compared to other semiconductor packages having the same volume as the semiconductor package 2010 or may be miniaturized compared to other semiconductor packages having the same capacity as the semiconductor package 2010, the mobile phone 2000 may be miniaturized and may have high performance.

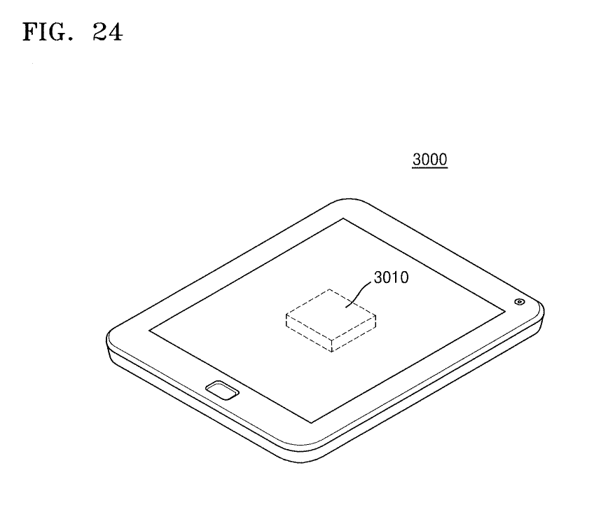

FIGS. 24 to 26 are diagrams of multimedia devices using a semiconductor package according to any one of the exemplary embodiments.

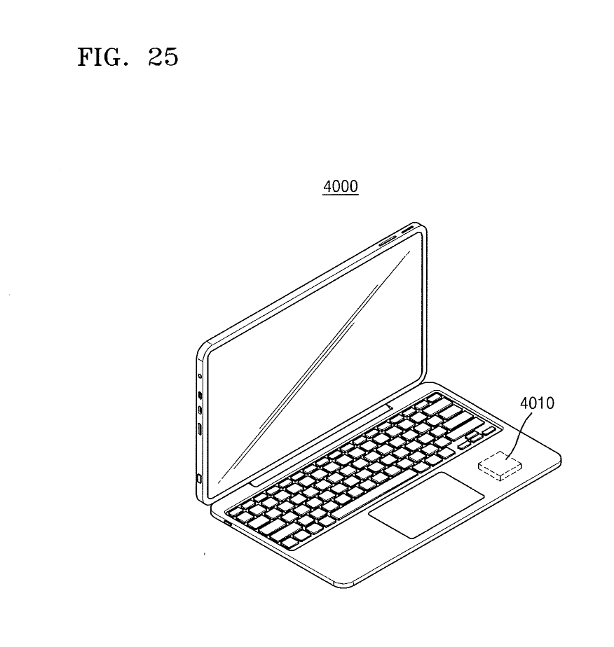

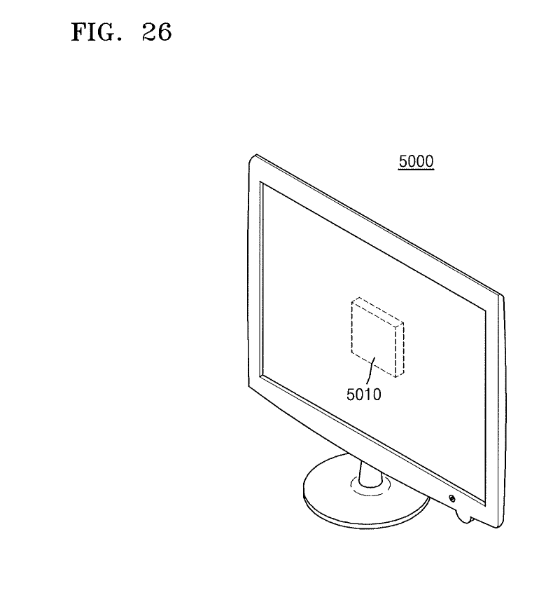

Referring to FIGS. 24 to 26, a semiconductor package according to any one of the exemplary embodiments may be applied to various multimedia devices. For example, a semiconductor package 3010 according to any one of the exemplary embodiments may be applied to a tablet or smart tablet 3000, as illustrated in FIG. 24. A semiconductor package 4010 according to any one of the exemplary embodiments may be applied to a notebook computer 4000, as illustrated in FIG. 25. In addition, a semiconductor package 5010 according to any one of the exemplary embodiments may be applied to a television or smart television 5000, as illustrated in FIG. 26. Since the tablet or smart tablet 3000, the notebook computer 4000, and the television or smart television 5000 uses a semiconductor package that has high reliability and that has relatively high capacity compared to other semiconductor packages having the same volume as the semiconductor package or may be miniaturized compared to other semiconductor packages having the same capacity as the semiconductor package, the tablet or smart tablet 3000, the notebook computer 4000, and the television or smart television 5000 may be miniaturized and may have high performance.

By way of summation and review, to form an encapsulant for encapsulating a semiconductor package, it is necessary to inject resin into a cavity of a mold in which the semiconductor package is accommodated. However, when the volume of the cavity of the mold is reduced to minimize the volume of the encapsulant, the injection of the resin is not smoothly performed, and thus, defects of the semiconductor package may occur.

In contrast, embodiments provide a release film for controlling a flow of resin that is injected to form an encapsulant for encapsulating a semiconductor package so as to prevent a defect of the semiconductor package. Embodiments also provide a method of manufacturing a semiconductor package using the release film. That is, the release film according to example embodiments may include hydrophilic regions and hydrophobic regions in accordance with different flow regions on the release film, so the flow of resin may be controlled to have a relatively uniform speed in accordance with the different hydrophilic and hydrophobic regions.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A release film for controlling a flow of resin, the release film comprising:
a backbone layer;
a mold release layer on a first surface of the backbone layer; and
a resin release layer on a second surface of the backbone layer, a surface of the resin release layer facing away from the backbone layer including regions having contact angles that are different from each other.

2. The release film as claimed in claim 1, wherein the resin release layer includes a first resin release layer and a second resin release layer sequentially attached to the backbone layer, the first resin release layer and the second resin release layer have different contact angles respective surfaces facing away from the backbone layer.

3. The release film as claimed in claim 2, wherein a contact angle in the first resin release layer is larger than that in the second resin release layer.

4. The release film as claimed in claim 2, wherein a contact angle in the second resin release layer is larger than that in the first resin release layer.

5. The release film as claimed in claim 1, wherein the surface of the resin release layer facing away from the backbone layer includes a first region and a second region, a contact angle in the first region being smaller than that in the second region.

6. The release film as claimed in claim 5, wherein the second region has a plurality of linear stripe shapes that extend in a first direction and are parallel to each other.

7. (canceled)

8. (canceled)

9. The release film as claimed in claim 5, wherein the second region has a plurality of chevron stripe shapes that are repeatedly arranged.

10. The release film as claimed in claim 5, wherein the second region has a plurality of bar shapes that are arranged in a matrix form.

11. (canceled)

12. (canceled)

13. The release film as claimed in claim 1, wherein the surface of the resin release layer facing away from the backbone layer includes regions having different average roughness values.

14. The release film as claimed in claim 1, wherein a contact angle in at least a part of the surface of the resin release layer facing away from the backbone layer has a gradient.

15. (canceled)

16. A release film for controlling a flow of resin, the release film comprising:
an adhesive surface; and
a resin flow control surface that is opposite to the adhesive surface, the resin flow control surface including first and second regions having contact angles that are different from each other.

17. The release film as claimed in claim 16, further comprising:
a backbone layer; and
a first resin release layer and a second resin release layer sequentially attached on the backbone layer to define the resin flow control surface,
wherein the first resin release layer and the second resin release layer have different contact angles in a surface opposite to the backbone layer, and
wherein the second resin release layer is in the second region.

18. The release film as claimed in claim 17, wherein the second region has a plurality of linear stripe shapes that are separately attached on the first resin release layer in parallel to each other.

19-21. (canceled)

22. The release film as claimed in claim 16, wherein the first resin release layer includes at least two regions having different average roughness values.

23. The release film as claimed in claim 16, wherein the second region of the resin flow control surface includes an uneven portion.

24-30. (canceled)

31. A release film for controlling a flow of resin, the release film comprising:
a backbone layer;
a mold release layer on a first surface of the backbone layer; and
a resin release layer on a second surface of the backbone layer, the second surface of the backbone layer being opposite the first surface, and a surface of the resin release layer facing away from the backbone layer including first surface portions having a first contact angle and second surface portions having a second contact angle larger than the first contact angle.

32. The release film as claimed in claim 31, wherein the first surface portions include a different material than the second surface portions.

33. The release film as claimed in claim 31, wherein the first surface portions exhibit a lower roughness value than the second surface portions.

34. The release film as claimed in claim 31, wherein the first surface portions are at a different distance from the second surface of the backbone layer relative to the second surface portions.

35. The release film as claimed in claim 31, wherein the first surface portions alternate with the second surface portions.
